(19) United States
(12) Patent Application Publication
(10) Pub. No.: US 2015/0188018 A1
(43) Pub. Date: Jul. 2, 2015

(54) THERMOELECTRIC GENERATOR SYSTEM

(71) Applicant: Panasonic Intellectual Property Management Co., Ltd., Osaka (JP)

(72) Inventors: Tsutomu KANNO, Kyoto (JP); Akihiro SAKAI, Nara (JP); Kohei TAKAHASHI, Osaka (JP); Hiromasa TAMAKI, Osaka (JP); Hideo KUSADA, Osaka (JP); Yuka YAMADA, Nara (JP)

(21) Appl. No.: 14/657,600

(22) Filed: Mar. 13, 2015

Related U.S. Application Data
(63) Continuation of application No. PCT/JP2013/004770, filed on Aug. 7, 2013.

(51) Int. Cl. H01L 35/30

(52) U.S. Cl. CPC H01L 35/30

(57) ABSTRACT

A thermoelectric generator system according to this disclosure includes a thermoelectric generator unit which performs thermoelectric generation using first and second heat transfer media at different temperatures. The unit includes a tubular thermoelectric generator which generates electromotive force in its axial direction based on a temperature difference between its inner and outer surfaces. The generator system further includes a flow rate control system which controls the flow rate of at least one of the first heat transfer medium flowing through a flow path defined by the inner surface and the second heat transfer medium in contact with the outer surface by reference to either information about an operation condition of the generator system or a preset target power output level.

This is a continuation of International Application No. PCT/JP2013/004770, with an international filing date of Aug. 7, 2013, the contents of which are hereby incorporated by reference.

### BACKGROUND

1. Technical Field

The present application relates to a thermoelectric generator system including a thermoelectric generator unit.

2. Description of the Related Art

A thermoelectric conversion element is an element which can convert either heat into electric power or electric power into heat. A thermoelectric conversion element made of a thermoelectric material that exhibits the Seebeck effect can obtain thermal energy from a heat source at a relatively low temperature (of 200 degrees Celsius or less, for example) and can convert the thermal energy into electric power. With a thermoelectric generation technique based on such a thermoelectric conversion element, it is possible to collect and effectively utilize thermal energy which would conventionally have been dumped unused into the ambient in the form of steam, hot water, exhaust gas, or the like.

A thermoelectric conversion element made of a thermoelectric material will be hereinafter referred to as a “thermoelectric generator”. A thermoelectric generator generally has a so-called “Π structure” where p- and n-type semiconductors, of which the carriers have mutually different electrical polarities, are combined together (see Japanese Laid-Open Patent Publication No. 2013-016685, for example). In a thermoelectric generator with the Π structure, a p-type semiconductor and an n-type semiconductor are connected together electrically in series together and thermally parallel with each other. In the Π structure, the direction of a temperature gradient and the direction of electric current flow are either mutually parallel or mutually antiparallel to each other. This makes it necessary to provide an output terminal on the high-temperature heat source side or the low-temperature heat source side. Consequently, to connect a plurality of such thermoelectric generators, each having the Π structure, electrically in series together, a complicated wiring structure is required.

PCT International Application Publication No. 2008/056466 (which will be hereinafter referred to as “Patent Document 1”) discloses a thermoelectric generator including a stacked body of a bismuth layer and a layer of a different metal from bismuth between first and second electrodes that face each other. In the thermoelectric generator disclosed in Patent Document 1, the planes of stacking are inclined with respect to a line that connects the first and second electrodes together. PCT International Application Publication No. 2012/014366 (which will be hereinafter referred to as “Patent Document 2”), kanno et al., preprints from the 72^{nd} Symposium of the Japan Society of Applied Physics, 30a-F-14 “A Tubular Electric Power Generator Using Off-Diagonal Thermoelectric Effects” (2011), and A. Sakai et al., International conference on thermoelectrics 2012 “Enhancement in performance of the tubular thermoelectric generator (TTEG)” (2012) disclose tubular thermoelectric generators. Japanese Laid-Open Patent Publication No. 11-274575 (which will be hereinafter referred to as “Patent Document 3”) discloses a thermoelectric generator apparatus in which a low-temperature heat exchange block, a thermoelectric generation module including a thermoelectric generator with the Π structure, and a high-temperature heat exchange block are stacked in this order a number of times. Patent Document says that by regulating individually the flow rates of a heat transfer medium to be supplied to each of a plurality of low-temperature heat exchange blocks and each of a plurality of high-temperature heat exchange blocks, variation in electric power generated between multiple thermoelectric generation modules can be minimized.

### SUMMARY

Development of a practical thermoelectric generator system that uses such thermoelectric generation technologies is awaited.

A thermoelectric generator system according to the present disclosure includes a thermoelectric generator unit which performs thermoelectric generation using first and second heat transfer media at mutually different temperatures. The thermoelectric generator unit includes a tubular thermoelectric generator which has an outer peripheral surface and an inner peripheral surface and which generates electromotive force in an axial direction of the tubular thermoelectric generator based on a difference in temperature between the inner and outer peripheral surfaces. The tubular thermoelectric generator includes a stacked body in which a first layer made of a first material with a relatively low Seebeck coefficient and relatively high thermal conductivity and a second layer made of a second material with a relatively high Seebeck coefficient and relatively low thermal conductivity are stacked alternately one upon the other and of which the plane of stacking is inclined with respect to the axial direction on a cross section including the axis of the tubular thermoelectric generator. The thermoelectric generator system further includes a flow rate control system which controls the flow rate of at least one of the first heat transfer medium flowing through a flow path defined by the inner peripheral surface and the second heat transfer medium that is in contact with the outer peripheral surface by reference to either information about an operation condition of the thermoelectric generator system or a preset target power output level.

A thermoelectric generator system according to the present disclosure contributes to increasing the practicality of thermoelectric power generation.

These general and specific aspects may be implemented using a system, a method, and a computer program, and any combination of systems, methods, and computer programs.

Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.

### BRIEF DESCRIPTION OF THE DRAWINGS

FIG. 1A is a schematic cross-sectional view of a thermoelectric generator 10.

FIG. 1B is a top view of the thermoelectric generator 10 shown in FIG. 1A.

FIG. 2 schematically illustrates a situation where a high-temperature heat source 120 is brought into contact with the upper surface 10a of the thermoelectric generator 10 and a low-temperature heat source 140 is brought into contact with its lower surface 10b.

FIG. 3A is a perspective view illustrating a general configuration for a tubular thermoelectric generator T which may be used in an exemplary thermoelectric generator system according to the present disclosure.

FIG. 3B is a perspective view illustrating a general configuration for an exemplary thermoelectric generator unit 100 that a thermoelectric generator system according to the present disclosure has.

FIG. 4 is a block diagram illustrating an exemplary configuration for introducing a temperature difference between the outer and inner peripheral surfaces of the tubular thermoelectric generator T.

FIG. 5 schematically illustrates how the tubular thermoelectric generators T1 to T10 may be electrically connected together.

FIG. 6A is a perspective view illustrating one of the tubular thermoelectric generators T (e.g., the tubular thermoelectric generator T1 in this example) that the thermoelectric generator system 100 has.

FIG. 6B schematically illustrates a cross section where the tubular thermoelectric generator T1 is cut along a plane which contains the axis (center axis) of the tubular thermoelectric generator T1.

FIG. 7A is a front view illustrating an implementation of a thermoelectric generator unit that the thermoelectric generator system according to the present disclosure has.

FIG. 7B illustrates one of the side faces of the thermoelectric generator unit 100 (a right side view in this case).

FIG. 8 illustrates a portion of an M-M cross section in FIG. 7B.

FIG. 9 schematically shows exemplary flow directions of the hot and cold heat transfer media introduced into the thermoelectric generator unit 100.

FIG. 10 is a graph showing how the electromotive force V generated by the tubular thermoelectric generator changes with the flow rate L of a hot heat transfer medium (at a temperature T) flowing through the thermoelectric generator unit.

FIG. 11 is a graph that plots two curves indicating typically how the electromotive force V changes with the flow rate L in the same tubular thermoelectric generator when the temperature of the hot heat transfer medium is T₀ and when the temperature of the hot heat transfer medium is T_{L}, respectively.

FIG. 12A is a graph schematically showing temperature distributions in the hot heat transfer medium, a thermoelectric material portion of the tubular thermoelectric generator, and the cold heat transfer medium when the flow rates of the hot and cold heat transfer media are relatively low.

FIG. 12B is a graph schematically showing temperature distributions in the hot heat transfer medium, a thermoelectric material portion of the tubular thermoelectric generator, and the cold heat transfer medium when the flow rate of the hot heat transfer medium is relatively high.

FIG. 13A is a graph schematically showing temperature distributions in the hot heat transfer medium, a thermoelectric material portion of the thermoelectric generator, and the cold heat transfer medium when the flow rate of the hot heat transfer medium is relatively low in a conventional Π-shaped thermoelectric generator.

FIG. 13B is a graph schematically showing temperature distributions in the hot heat transfer medium, a thermoelectric material portion of the thermoelectric generator, and the cold heat transfer medium when the flow rate of the hot heat transfer medium is relatively high in the conventional Π-shaped thermoelectric generator.

FIG. 14 is an exemplary graph showing a relation between the electromotive force and ΔT.

FIG. 15 is an exemplary graph showing the potential difference dependences of electric current and a power output level in a tubular thermoelectric generator.

FIG. 16 is a graph schematically showing how the hot heat transfer medium flowing through the thermoelectric generator unit may vary with time.

FIG. 17 is a graph schematically showing how the power output level changes significantly (as indicated by the dotted curve) as the flow rate of the hot heat transfer medium flowing through the thermoelectric generator unit varies with time.

FIG. 18A is a block diagram illustrating an exemplary configuration for a thermoelectric generator system according to an embodiment of the present disclosure.

FIG. 18B is a block diagram illustrating another exemplary configuration for a thermoelectric generator system according to an embodiment of the present disclosure.

FIG. 19 illustrates a first exemplary basic configuration for a thermoelectric generator system according to an embodiment of the present disclosure.

FIG. 20 illustrates a second exemplary basic configuration for a thermoelectric generator system according to an embodiment of the present disclosure.

FIG. 21 illustrates a third exemplary basic configuration for a thermoelectric generator system according to an embodiment of the present disclosure.

FIG. 22 illustrates an exemplary configuration for a flow rate control section 530.

FIG. 23 illustrates another exemplary configuration for the flow rate control section 530.

FIG. 24 illustrates still another exemplary configuration for the flow rate control section 530.

FIG. 25 illustrates yet another exemplary configuration for the flow rate control section 530.

FIG. 26 illustrates yet another exemplary configuration for the flow rate control section 530.

FIG. 27 illustrates yet another exemplary configuration for the flow rate control section 530.

FIG. 28 schematically illustrates a cross section of a portion of a plate 36 and the appearance of an electrically conductive member J1.

FIG. 29A is an exploded perspective view schematically illustrating the channel C61 to house the electrically conductive member J1 and its vicinity.

FIG. 29B is a perspective view schematically illustrating a portion of the sealing surface of the second plate portion 36b (i.e., the surface that faces the first plate portion 36a) associated with the openings A61 and A62.

FIG. 30A is a perspective view illustrating an exemplary shape of the electrically conductive ring member 56.

FIG. 30B is a perspective view illustrating another exemplary shape of the electrically conductive ring member 56.

FIG. 31A is a cross-sectional view schematically illustrating the electrically conductive ring member 56 and tubular thermoelectric generator T1.

FIG. 31B is a cross-sectional view schematically illustrating a state where an end of the tubular thermoelectric generator T1 has been inserted into the electrically conductive ring member 56.

FIG. 31C is a cross-sectional view schematically illustrating a state where an end of the tubular thermoelectric generator T1 has been inserted into the electrically conductive ring member 56 and electrically conductive member J1.

FIG. 32A is a cross-sectional view schematically illustrating the electrically conductive ring member 56 and a portion of the electrically conductive member J1.

FIG. 32B is a cross-sectional view schematically illustrating a state where the elastic portions 56r of the electrically conductive ring member 56 have been inserted into the through hole Jh1 of the electrically conductive member J1.

FIG. 33 is a cross-sectional view illustrating an exemplary tubular thermoelectric generator T with a chamfered portion Cm at its end.

FIG. 34A schematically illustrates how electric current flows in tubular thermoelectric generators T which are electrically connected together in series.

FIG. 34B schematically illustrates how electric current flows in tubular thermoelectric generators T which are electrically connected together in series.

FIG. 35 schematically shows the directions in which electric current flows through the two openings A61 and A62 and their surrounding region.

FIG. 36A is a perspective view illustrating an exemplary tubular thermoelectric generator, of which the electrodes have indicators of their polarity.

FIG. 36B is a perspective view illustrating another exemplary tubular thermoelectric generator, of which the electrodes have indicators of their polarity.

FIG. 37 illustrates the other side face of the thermoelectric generator unit 100 shown in FIG. 7A (left side view).

FIG. 38 schematically illustrates a cross section of a portion of a plate 34 and the appearance of an electrically conductive member K1.

FIG. 39 is an exploded perspective view schematically illustrating the channel C41 to house the electrically conductive member K1 and its vicinity.

FIG. 40 is a cross-sectional view illustrating an exemplary structure for separating the medium in contact with the outer peripheral surface of each of the tubular thermoelectric generators T1 to T10 from the medium in contact with the inner peripheral surface of the tubular thermoelectric generator T so as to prevent those media from mixing together.

FIG. 41A is a cross-sectional view illustrating another exemplary structure for separating the hot and cold heat transfer media from each other and electrically connecting the tubular thermoelectric generator and the electrically conductive member together.

FIG. 41B is a cross-sectional view illustrating still another exemplary structure for separating the hot and cold heat transfer media from each other and electrically connecting the tubular thermoelectric generator and the electrically conductive member together.

FIG. 42A illustrates an exemplary configuration for a thermoelectric generator system according to the present disclosure.

FIG. 42B is a schematic cross-sectional view of the system as viewed on the plane B-B shown in FIG. 42A.

FIG. 42C is a perspective view illustrating an exemplary configuration for a buffer vessel that the thermoelectric generator system shown in FIG. 42A has.

FIG. 43 illustrates still another exemplary configuration for a thermoelectric generator system according to the present disclosure.

FIG. 44 is a block diagram illustrating an exemplary configuration of an electric circuit that the thermoelectric generator system according to the present disclosure may include.

FIG. 45 is a block diagram illustrating an exemplary configuration for another embodiment in which a thermoelectric generator system according to the present disclosure may be used.

### DETAILED DESCRIPTION

A thermoelectric generator system according to a non-limiting, exemplary implementation of the present disclosure includes a thermoelectric generator unit which performs thermoelectric generation using first and second heat transfer media at mutually different temperatures. This thermoelectric generator unit includes at least one tubular thermoelectric generator which has an outer peripheral surface and an inner peripheral surface. The tubular thermoelectric generator includes a stacked body in which a first layer made of a first material with a relatively low Seebeck coefficient and relatively high thermal conductivity and a second layer made of a second material with a relatively high Seebeck coefficient and relatively low thermal conductivity are stacked alternately one upon the other. On a cross section including the axis of the tubular thermoelectric generator, the plane of stacking of this stacked body is inclined with respect to the axial direction. This tubular thermoelectric generator generates electromotive force in an axial direction of the tubular thermoelectric generator based on a difference in temperature between the inner and outer peripheral surfaces.

In an embodiment of the present disclosure, the thermoelectric generator system may further includes an input interface which gets the target power output level.

A thermoelectric generator system according to an embodiment of the present disclosure further includes a flow rate control system which controls the flow rate of at least one of the first heat transfer medium flowing through a flow path defined by the inner peripheral surface of the tubular thermoelectric generator and the second heat transfer medium that is in contact with the outer peripheral surface of the tubular thermoelectric generator by reference to either information about an operation condition of the thermoelectric generator system or a preset target power output level.

In the present specification, one of the first and second heat transfer media will be sometimes hereinafter referred to as a “hot heat transfer medium” and the other as a “cold heat transfer medium”. It should be noted that although these heat transfer media will be referred to herein as “hot” and “cold” heat transfer media, these terms “hot” and “cold” actually do not refer to specific absolute temperature levels of those media but just mean that there is a relative temperature difference between those media. Also, the “medium” is typically a gas, a liquid or a fluid that is a mixture of a gas and a liquid. However, the “medium” may contain solid, e.g., powder, which is dispersed within a fluid. Hereinafter, the hot heat transfer medium and the cold heat transfer medium will be sometimes simply referred to as “the hot medium” and “the cold medium”, respectively.

In an embodiment of the present disclosure, the information about the operation condition of the thermoelectric generator system may include an electrical parameter indicating the power output level of the thermoelectric generator system (which may be at least one of electric power, voltage, and electric current, for example). These parameters may be measured by a voltmeter or an ammeter, for example. In one embodiment, the flow rate control system may set the flow rate to be a value falling within a “non-saturated region” in which the power output level rises as the flow rate of at least one of the first and second heat transfer media increases. The flow rate control system may be configured to increase the flow rate of at least one of the first and second heat transfer media flowing through the thermoelectric generator unit if the “information” indicates that the power output level has declined. It will be described in detail later how the flow rate control section operates in that non-saturated region.

The “information” about the operation condition of the thermoelectric generator system may include the “temperature” of at least one of the first and second heat transfer media. This temperature may be measured by arranging a known sensor such as a thermometer in at least one position along the flow path of the heat transfer medium. The flow rate control system may be configured to increase the flow rate of at least one of the first and second heat transfer media flowing through the thermoelectric generator unit if the “information” indicates that the difference in temperature between the first and second heat transfer media has decreased.

In one embodiment, the thermoelectric generator system may be connected to first and second supply sources of the first and second heat transfer media through first and second flow paths, respectively. At least one of a rate at which the first heat transfer medium is supplied from the first supply source and a rate at which the second heat transfer medium is supplied from the second supply source may vary with time. Such an embodiment of the present disclosure is applicable particularly effectively to a situation where the rate of supply of a heat transfer medium is variable.

In one embodiment of the present disclosure, the flow rate control system may include a first flow rate control section connected to the first flow path. The first flow rate control section may include: a first storage container configured to store the first heat transfer medium temporarily; and a first regulator which regulates the flow rate of the first heat transfer medium that flows from inside of the first storage container into the thermoelectric generator unit so that the flow rate falls within a preset range. The first storage container may be connected either in series or parallel with the first flow path.

In one embodiment of the present disclosure, the flow rate control system may include a second flow rate control section connected to the second flow path. The second flow rate control section may include: a second storage container configured to store the second heat transfer medium temporarily; and a second regulator which regulates the flow rate of the second heat transfer medium that flows from inside of the second storage container into the thermoelectric generator unit so that the flow rate falls within a preset range. The second storage container may be connected either in series or parallel with the second flow path.

The information about the operation condition of the thermoelectric generator system may include at least one of a rate at which the first heat transfer medium is supplied and a rate at which the second heat transfer medium is supplied.

At least one of the first and second flow paths may be a circuit configured to make the heat transfer medium that has left the supply source go back to the same supply source again.

In one embodiment of the present disclosure, the thermoelectric generator unit may further includes a container to house the tubular thermoelectric generator inside. The container may have a fluid inlet port and a fluid outlet port to make the second heat transfer medium flow inside the container and an opening into which the tubular thermoelectric generator is inserted.

<Basic Configuration and Principle of Operation of Thermoelectric Generator>

Before embodiments of a thermoelectric generator system according to the present disclosure are described, the basic configuration and principle of operation of a thermoelectric generator for use in each thermoelectric generator unit that the thermoelectric generator system has will be described. As will be described later, in a thermoelectric generator system according to the present disclosure, a tubular thermoelectric generator is used. However, the principle of operation of such a tubular thermoelectric generator can also be understood more easily through description of the principle of operation of a thermoelectric generator in a simpler shape.

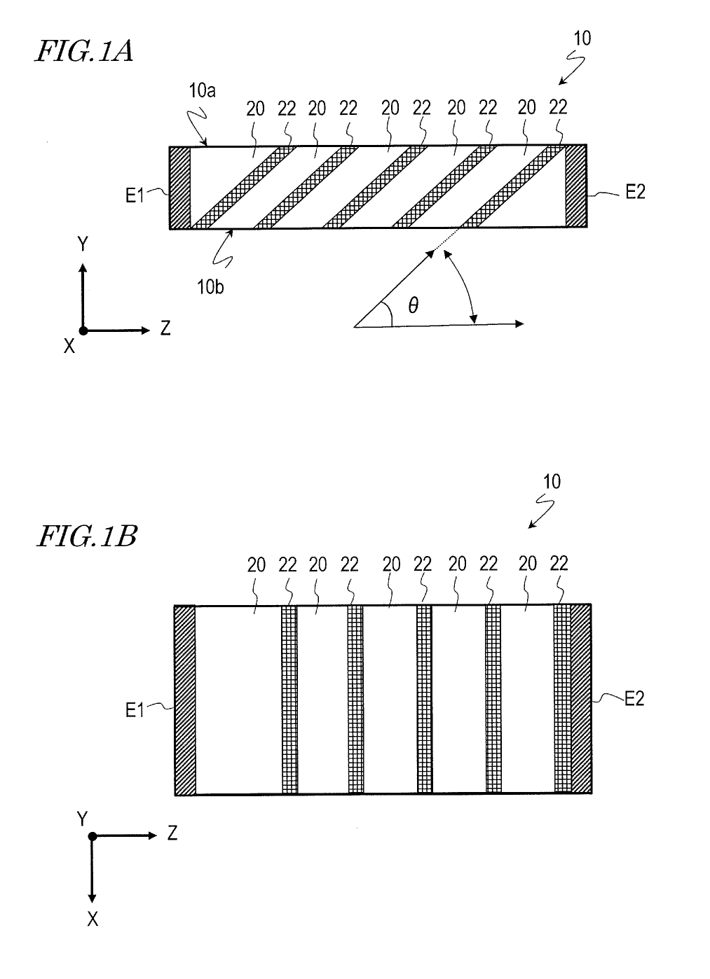

First of all, look at FIGS. 1A and 1B. FIG. 1A is a schematic cross-sectional view of a thermoelectric generator 10 with a generally rectangular parallelepiped shape, and FIG. 1B is a top view of the thermoelectric generator 10. For reference sake, X-, Y- and Z-axis that intersect with each other at right angles are shown in FIGS. 1A and 1B. The thermoelectric generator 10 shown in FIGS. 1A and 1B includes a stacked body with a structure in which multiple metal layers and thermoelectric material layers 22 are alternately stacked one upon the other so that their planes of stacking are inclined. Although the stacked body is supposed to have a rectangular parallelepiped shape in this example, the principle of operation will be the same even if the stacked body has any other shape.

In the thermoelectric generator 10 shown in FIGS. 1A and 1B, first and second electrodes E1 and E2 are arranged so as to sandwich the stacked body horizontally between them. In the cross section shown in FIG. 1A, the planes of stacking define an angle of inclination θ (where 0<θ<Π radians) with respect to the Z-axis direction. The angle of inclination θ will be hereinafter simply referred to as an “inclination angle”.

In the thermoelectric generator 10 with such a configuration, when a temperature difference is created between its upper surface 10a and its lower surface 10b, the heat will be transferred preferentially through the metal layers 20 with higher thermal conductivity than the thermoelectric material layers 22. Thus, a Z-axis direction component is produced in the temperature gradient of each of those thermoelectric material layers 22. As a result, electromotive force occurs in the Z-axis direction in each thermoelectric material layer 22 due to the Seebeck effect, and eventually the electromotive forces are superposed one upon the other in series inside this stacked body. Consequently, a significant potential difference is created as a whole between the first and second electrodes E1 and E2. A thermoelectric generator including the stacked body shown in FIGS. 1A and 1B is disclosed in PCT International Application Publication No. 2008/056466 (Patent Document 1), the entire disclosure of which is hereby incorporated by reference.

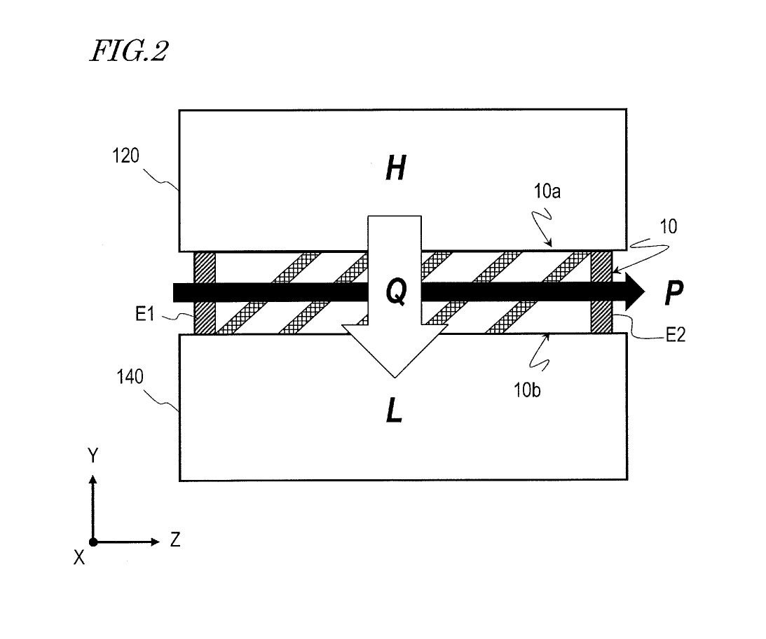

FIG. 2 schematically illustrates a situation where a high-temperature heat source 120 is brought into contact with the upper surface 10a of the thermoelectric generator 10 and a low-temperature heat source 140 is brought into contact with its lower surface 10b. In such a situation, heat Q flows from the high-temperature heat source 120 toward the low-temperature heat source 140 through the thermoelectric generator 10, and electric power P can be extracted from the thermoelectric generator 10 through the first and second electrodes E1 and E2. From a macroscopic point of view, in this thermoelectric generator 10, the direction of temperature gradient (Y-axis direction) and the direction of the electric current (Z-axis direction) intersect with each other at right angles. That is why there is no need to create a temperature difference between the two electrodes E1 and E2, through which the electric power is extracted. FIG. 2 schematically illustrates an example in which the electric power P flows from the left toward the right on the paper. However, this is only an example. For example, if the kind of the thermoelectric material used to make the thermoelectric generator 10 is changed, the electric power P may flow in the opposite direction from the one shown in FIG. 2.

Although the stacked body of the thermoelectric generator 10 is supposed to have a rectangular parallelepiped shape in the example described above for the sake of simplicity, a thermoelectric generator, of which the stacked body has a tubular shape, will be used in the embodiments to be described below. A thermoelectric generator in such a tubular shape will be hereinafter referred to as a “tubular thermoelectric generator”. It should be noted that in the present specification, the term “tube” is interchangeably used with the term “pipe”, and is to be interpreted to encompass both a “tube” and a “pipe”.

<Outline of Thermoelectric Generator Unit>

Next, a thermoelectric generator unit of the thermoelectric generator system according to the present disclosure will be outlined.

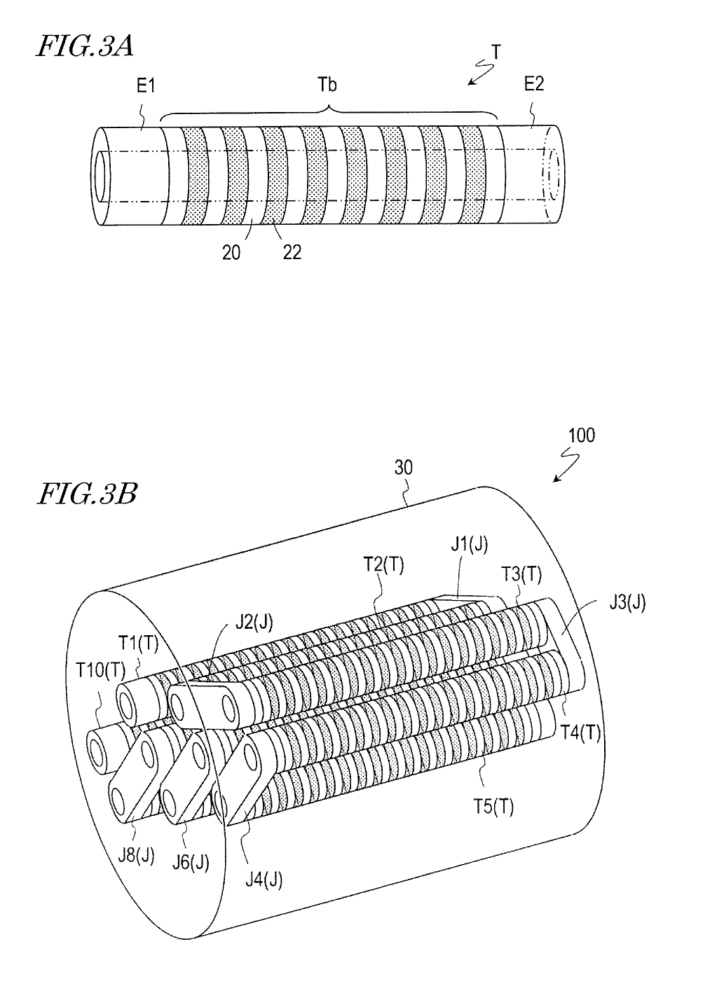

First of all, look at FIGS. 3A and 3B. FIG. 3A is a perspective view illustrating an exemplary tubular thermoelectric generator T. The tubular thermoelectric generator T includes a tube body Tb in which multiple metal layers 20 and thermoelectric material layers 22 with a through hole at their center are alternately stacked one upon the other so as to be inclined and a pair of electrodes E1 and E2. A method of making such a tubular thermoelectric generator T is disclosed in Patent Document 2, for example. According to the method disclosed in Patent Document 2, multiple metallic cups, each having a hole at the bottom, and multiple thermoelectric material cups, each also having a hole at the bottom, are alternately stacked one upon the other and subjected to a plasma sintering process in such a state, thereby binding them together. The entire disclosure of PCT International Application Publication No. 2012/014366 is hereby incorporated by reference.

The tubular thermoelectric generator T shown in FIG. 3A may be connected to a conduit so that a hot medium flows through a flow path defined by its inner peripheral surface (which will be sometimes hereinafter referred to as an “internal flow path”). In that case, the outer peripheral surface of the tubular thermoelectric generator T may be brought into contact with a cold medium. In this manner, a temperature difference is created between the inner and outer peripheral surfaces of the tubular thermoelectric generator T, thereby generating a potential difference between the pair of electrodes E1 and E2. As a result, the electric power generated can be extracted.

The shape of the tubular thermoelectric generator T may be anything tubular, without being limited to cylindrical. In other words, when the tubular thermoelectric generator T is cut along a plane which is perpendicular to the axis of the tubular thermoelectric generator T, the resultant shapes created by sections of the “outer peripheral surface” and the “inner peripheral surface” do not need to be circles, but may be any closed curves, e.g., ellipses or polygons. Although the axis of the tubular thermoelectric generator T is typically linear, it is not limited to being linear. These can be seen easily from the principle of thermoelectric generation that has already been described with reference to FIGS. 1A, 1B and 2.

FIG. 3B is a perspective view illustrating a general configuration for an exemplary thermoelectric generator unit 100 that a thermoelectric generator system according to the present disclosure has. The thermoelectric generator unit 100 shown in FIG. 3B includes the tubular thermoelectric generators T described above. In the example illustrated in FIG. 3B, ten tubular thermoelectric generators T1 to T10 are housed inside a container 30. Those ten tubular thermoelectric generators T1 to T10 are typically arranged substantially parallel to each other but may also be arranged in any other pattern.

As shown in FIG. 3B, the thermoelectric generator unit 100 may include such a container 30 to house those tubular thermoelectric generators T inside. If the thermoelectric generator unit 100 has a number of tubular thermoelectric generators T, then the thermoelectric generator unit 100 may have a plurality of electrically conductive members J to electrically connect those tubular thermoelectric generators T together.

Each of these tubular thermoelectric generators T1 to T10 has an outer peripheral surface, an inner peripheral surface and an internal flow path defined by the inner peripheral surface as described above. Each of these tubular thermoelectric generators T1 to T10 is configured to generate electromotive force along its axis based on a difference in temperature created between the inner and outer peripheral surfaces. That is to say, by creating a temperature difference between the outer and inner peripheral surfaces in each of those tubular thermoelectric generators T1 to T10, electric power generated can be extracted from the tubular thermoelectric generators T1 to T10. For example, by bringing a hot medium and a cold medium into contact with the internal flow path and the outer peripheral surface, respectively, in each of the tubular thermoelectric generators T1 to T10, electric power generated can be extracted from the tubular thermoelectric generators T1 to T10. Conversely, a cold medium and a hot medium may be brought into contact with the inner and outer peripheral surfaces, respectively, in each of the tubular thermoelectric generators T1 to T10.

In the example illustrated in FIG. 3B, the medium to be brought into contact with the outer peripheral surfaces of the tubular thermoelectric generators T1 to T10 inside the container 30 and the medium to be brought into contact with the inner peripheral surface of each tubular thermoelectric generator T1 to T10 in the internal flow path of the respective tubular thermoelectric generator are supplied through different conduits (not shown), thus being isolated so as not to intermix.

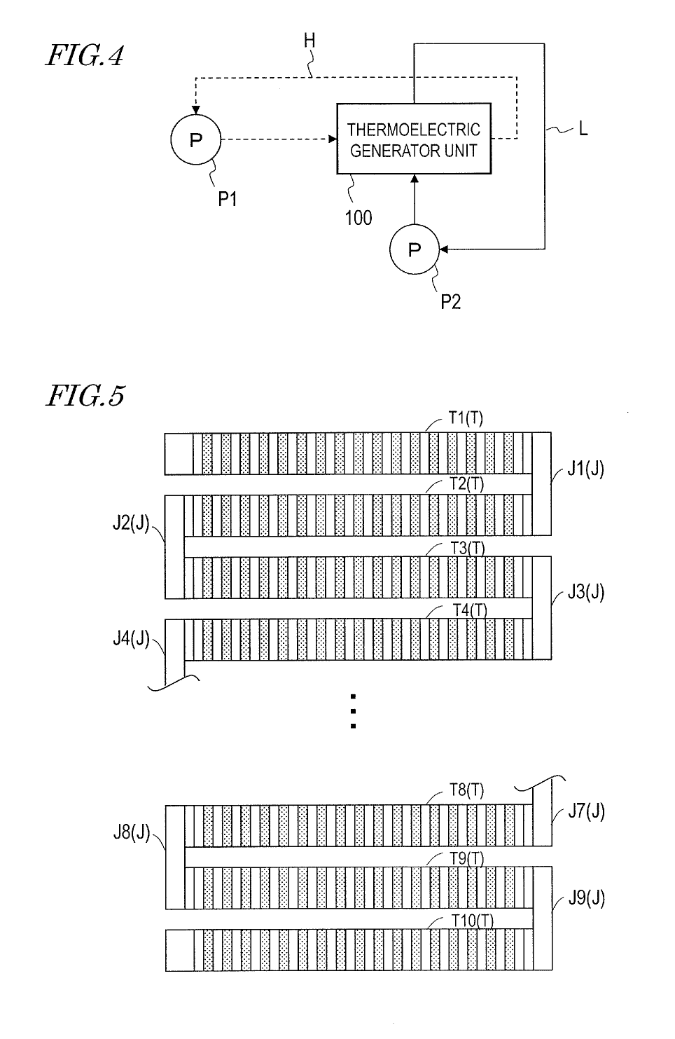

FIG. 4 is a block diagram illustrating an exemplary configuration for introducing a temperature difference between the outer and inner peripheral surfaces of the tubular thermoelectric generator T. In FIG. 4, the dotted arrow H schematically indicates the flow of a hot medium and the solid arrow L schematically indicates the flow of a cold medium. In the example illustrated in FIG. 4, the hot and cold media are circulated by pumps P1 and P2, respectively. For example, the hot medium may be supplied to the internal flow path in each of the tubular thermoelectric generators T1 to T10 and the cold medium may be supplied into the container 30. Although not shown in FIG. 4, heat is supplied from a high-temperature heat source (such as a heat exchanger, not shown) to the hot medium and heat is supplied from the cold medium to a low-temperature heat source (not shown, either). As the high-temperature heat source, steam, hot water and exhaust gas at relatively low temperatures (of 200 degrees Celsius or less, for example) which have been dumped unused into the ambient can be used. Naturally, heat sources at even higher temperatures may also be used.

In the example illustrated in FIG. 4, the hot and cold media are supposed to be circulated by the pumps P1 and P2, respectively. However, this is only an example of a thermoelectric generator system according to the present disclosure. Alternatively, one or both of the hot and cold media may be dumped from their heat source into the ambient without forming a circulating system. For example, high-temperature hot spring water that has sprung from the ground may be supplied as the hot medium to the thermoelectric generator unit 100, and when its temperature lowers, the hot spring water may be used for any purpose other than power generation or just discharged. The same can be said about the cold medium. That is to say, phreatic water, river water or seawater may be pumped up and supplied to the thermoelectric generator unit 100. After any of these kinds of water has been used as the cold medium, its temperature may be lowered to an appropriate level as needed and then the water may be either poured back to its original source or just discharged to the ambient.

Now look at FIG. 3B again. As shown in FIG. 3B, if the thermoelectric generator unit 100 has a plurality of tubular thermoelectric generators T, those tubular thermoelectric generators T are electrically connected together via the electrically conductive members J. In the example illustrated in FIG. 3B, each pair of tubular thermoelectric generators T arranged adjacent to each other are connected together via their associated electrically conductive member J. As a result, these tubular thermoelectric generators T are electrically connected together in series as a whole. For example, the respective right ends of two tubular thermoelectric generators T3 and T4 which are illustrated as front ones in FIG. 3B are connected together with an electrically conductive member J3. On the other hand, the respective left ends of these two tubular thermoelectric generators T3 and T4 are connected to two other tubular thermoelectric generators T2 and T5 via electrically conductive members J2 and J4, respectively.

FIG. 5 schematically illustrates how those tubular thermoelectric generators T1 to T10 may be electrically connected together. As shown in FIG. 5, each of the electrically conductive members J1 to J9 electrically connects its associated two tubular thermoelectric generators together. That is to say, the electrically conductive members J1 to J9 are arranged to electrically connect these tubular thermoelectric generators T1 to T10 in series together as a whole. In this example, the circuit comprised of the tubular thermoelectric generators T1 to T10 and the electrically conductive members J1 to J9 is a traversable one. However, this circuit may also include some tubular thermoelectric generators which are connected in parallel, and it is not essential that the circuit be traversable.

In the example illustrated in FIG. 5, an electric current may flow from the tubular thermoelectric generator T1 to the tubular thermoelectric generator T10, for example. However, the electric current may also flow from the tubular thermoelectric generator T10 to the tubular thermoelectric generator T1. The direction of this electric current is determined by the kind of a thermoelectric material used to make the tubular thermoelectric generator T, the direction of flow of heat generated between the inner and outer peripheral surfaces of the tubular thermoelectric generator T and the direction of inclination of the planes of stacking in the tubular thermoelectric generator T, for example.

The connection of the tubular thermoelectric generators T1 to T10 is determined so that electromotive forces occurring in the respective tubular thermoelectric generators T1 to T10 do not cancel one another, but are superposed.

It should be noted that the direction in which the electric current flows through the tubular thermoelectric generators T1 to T10 has nothing to do with the direction in which the medium (i.e., either the hot medium or the cold medium) flows through the internal flow path of the tubular thermoelectric generators T1 to T10. For instance, in the example illustrated in FIG. 5, the medium going through the internal flow path may flow from the left toward the right on the paper in each and every one of the tubular thermoelectric generators T1 to T10.

<Detailed Configuration of Tubular Thermoelectric Generator T>

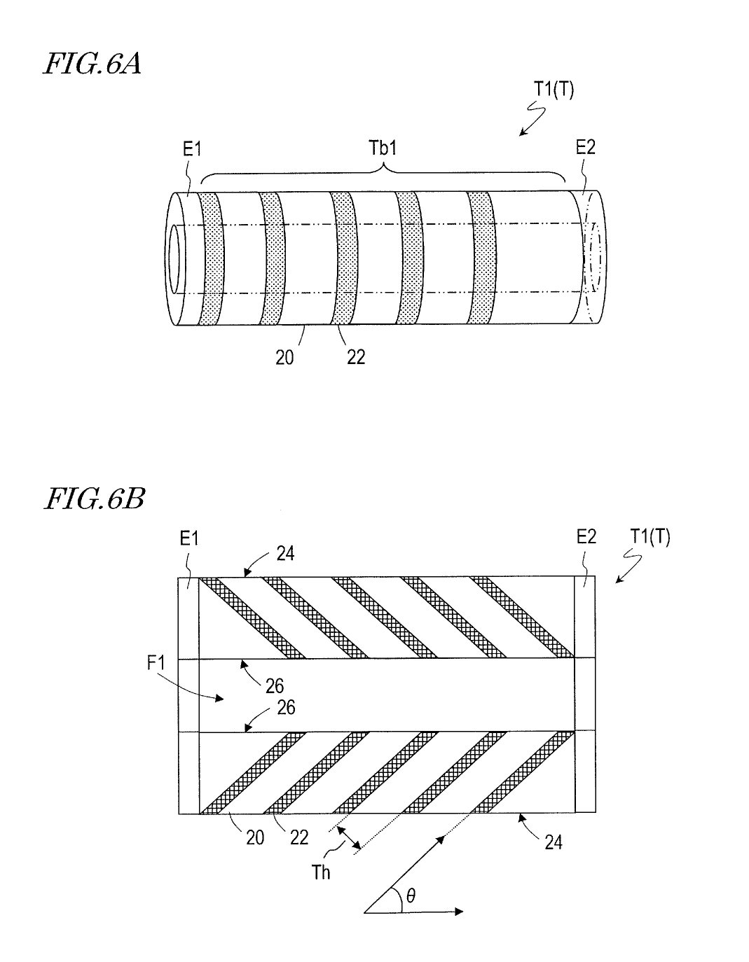

Next, a detailed configuration for the tubular thermoelectric generator T will be described with reference to FIGS. 6A and 6B. FIG. 6A is a perspective view illustrating one of the tubular thermoelectric generators T (e.g., the tubular thermoelectric generator T1 in this example) that the thermoelectric generator system 100 has. The tubular thermoelectric generator T1 includes a tube body Tb1 and first and second electrodes E1 and E2 which are arranged at both ends of the tube body Tb1. The tube body Tb1 has a configuration in which multiple metal layers 20 and multiple thermoelectric material layers 22 are alternately stacked one upon the other. In the present specification, the direction in which a line that connects the first and second electrodes E1 and E2 together runs will be sometimes hereinafter referred to as a “stacking direction”. The stacking direction agrees with the axial direction of the tubular thermoelectric generator.

FIG. 6B schematically illustrates a cross section of the tubular thermoelectric generator T1 as viewed on a plane including the axis (center axis) of the tubular thermoelectric generator T1. As shown in FIG. 6B, the tubular thermoelectric generator T1 has an outer peripheral surface 24 and an inner peripheral surface 26. A region which is defined by the inner peripheral surface 26 forms a flow path F1. In the illustrated example, cross sections of the outer peripheral surface 24 and the inner peripheral surface 26 taken perpendicular to the axial direction each present the shape of a circle. However, these shapes are not limited to circles, but may be ellipses or polygons, as described above. The cross-sectional area of the flow path on such a cross section that intersects with the axial direction at right angles is not particularly limited. But the cross-sectional area of the flow path or the number of tubular thermoelectric generators to provide may be determined appropriately by the flow rate of the medium to be supplied into the internal flow path of the tubular thermoelectric generator T.

Although the first and second electrodes E1 and E2 each have a circular cylindrical shape in the example illustrated in FIG. 6A, this is only an example and the first and second electrodes E1 and E2 do not have to have such a shape. At or near the respective end of the tube body Tb1, the first electrode E1 and the second electrode E2 may each have any arbitrary shape which is electrically connectable to at least one of the metal layers 20 or the thermoelectric material layers 22 and which does not obstruct the flow path F1. In the example shown in FIGS. 6A and 6B, the first electrode E1 and the second electrode E2 have outer peripheral surfaces conforming to the outer peripheral surface 24 of the tube body b1; however, it is not necessary for the outer peripheral surfaces of the first electrode E1 and the second electrode E2 to conform to the outer peripheral surface 24 of the tube body b1. For example, the diameter of the outer peripheral surface (i.e., the outer diameter) of the first and second electrodes E1 and E2 may be larger or smaller than that of the tube body b1. Also, when viewed on a plane that intersects with the axial direction at right angles, the cross-sectional shape of the first and second electrodes E1 and E2 may be different from that of the outer peripheral surface 24 of the tube body Tb1.

The first and second electrodes E1 and E2 may be made of a material with electrical conductivity and are typically made of a metal. The first and second electrodes E1 and E2 may be comprised of a single or multiple metal layers 20 which are located at or near the ends of the tube body Tb1. In that case, portions of the tube body Tb1 function as the first and second electrodes E1 and E2. Alternatively, the first and second electrodes E1 and E2 may also be formed out of a metal layer or annular metallic member which is arranged so as to partially cover the outer peripheral surface of the tube body Tb1. Still alternatively, the first and second electrodes E1 and E2 may also be a pair of circular cylindrical metallic members which are fitted into the flow path F1 through the ends of the tube body Tb1 so as to be in contact with the inner peripheral surface of the tube body Tb1.

As shown in FIG. 6B, the metal layers 20 and thermoelectric material layers 22 are alternately stacked one upon the other so as to be inclined. That is to say, on a cross section including the axis of the tubular thermoelectric generator T, the planes of stacking of the stacked body in which the metal layers 20 and thermoelectric material layers are alternately stacked one upon the other define an inclination angle with respect to the axial direction of the tubular thermoelectric generator T. A tubular thermoelectric generator with such a configuration operates on basically the same principle as what has already been described with reference to FIGS. 1A, 1B and 2. That is why if a temperature difference is created between the outer peripheral surface 24 and inner peripheral surface 26 of the tubular thermoelectric generator T1, a potential difference is generated between the first and second electrodes E1 and E2. The general direction of the temperature gradient is the radial direction of the tubular thermoelectric generator T1 (i.e., the direction that intersects with the stacking direction at right angles).

The inclination angle θ of the planes of stacking in the tube body Tb1 may be set within the range of not less than 5 degrees and not more than 60 degrees, for example. The inclination angle θ may be not less than 20 degrees and not more than 45 degrees. An appropriate range of the inclination angle θ varies according to the combination of the material to make the metal layers 20 and the thermoelectric material to make the thermoelectric material layers 22.

The ratio of the thickness of each metal layer 20 to that of each thermoelectric material layer 22 in the tube body Tb1 (which will be hereinafter simply referred to as a “stacking ratio”) may be set within the range of 20:1 to 1:9, for example. In this case, the thickness of the metal layer 20 refers herein to its thickness as measured perpendicularly to the plane of stacking (i.e., the thickness indicated by the arrow Th in FIG. 6B). In the same way, the thickness of the thermoelectric material layer 22 refers herein to its thickness as measured perpendicularly to the plane of stacking. It should be noted that the total number of the metal layers 20 and thermoelectric material layers 22 that are stacked one upon the other may be set appropriately.

The metal layers 20 may be made of any arbitrary metallic material. For example, the metal layers 20 may be made of nickel or cobalt. Nickel and cobalt are examples of metallic materials which exhibit excellent thermoelectric generation properties. Optionally, the metal layers 20 may include silver or gold. Furthermore, the metal layers 20 may include any of these metallic materials either by itself or as their alloy. If the metal layers 20 are made of an alloy, the alloy may include copper, chromium or aluminum. Examples of such alloys include constantan, CHROMEL™, and ALUMEL™.

The thermoelectric material layers 22 may be made of any arbitrary thermoelectric material depending on their operating temperature. Examples of thermoelectric materials which may be used to make the thermoelectric material layers 22 include: thermoelectric materials of a single element, such as bismuth or antimony; alloy-type thermoelectric materials, such as BiTe-type, PbTe-type and SiGe-type; and oxide-type thermoelectric materials, such as CaₓCoO₂, NaₓCoO₂ and SrTiO₃. In the present specification, the “thermoelectric material” refers herein to a material, of which the Seebeck coefficient has an absolute value of 30 μV/K or more and the electrical resistivity is 10 mΩcm or less. Such a thermoelectric material may be a crystalline one or an amorphous one. If the hot medium has a temperature of approximately 200 degrees Celsius or less, the thermoelectric material layers 22 may be made of a dense body of bismuth-antimony-tellurium, for example. Bismuth-antimony-tellurium may be, but does not have to be, represented by a chemical composition Bi_{0.5}Sb_{1.5}Te₃. Optionally, bismuth-antimony-tellurium may include a dopant such as selenium. The mole fractions of bismuth and antimony may be adjusted appropriately.

Other examples of the thermoelectric materials to make the thermoelectric material layers 22 include bismuth telluride and lead telluride. When the thermoelectric material layers 22 are made of bismuth telluride, it may be of the chemical composition Bi₂Teₓ, where 2<X<4. A representative chemical composition of bismuth telluride is Bi₂Te₃, which may include antimony or selenium. The chemical composition of bismuth telluride including antimony may be represented by (Bi_{1-Y}Sb_{Y})₂Teₓ, where 0<Y<1, and more preferably 0.6<Y<0.9.

The first and second electrodes E1 and E2 may be made of any material as long as the material has good electrical conductivity. For example, the first and second electrodes E1 and E2 may be made of a metal selected from the group consisting of nickel, copper, silver, molybdenum, tungsten, aluminum, titanium, chromium, gold, platinum and indium. Alternatively, the first and second electrodes E1 and E2 may also be made of a nitrides or oxides, such as titanium nitride (TiN), indium tin oxide (ITO), and tin dioxide (SnO₂). Still alternatively, the first or second electrode E1, E2 may also be made of solder, silver solder or electrically conductive paste, for example. It should be noted that if both ends of the tube body Tb1 are metal layers 20, then the first and second electrodes E1 and E2 may be replaced with those metal layers 20 as described above.

In the foregoing description, an element with a configuration in which metal layers and thermoelectric material layers are alternately stacked one upon the other has been described as a typical example of a tubular thermoelectric generator. However, this is just an example, and the tubular thermoelectric generator which may be used according to the present disclosure does not have to have such a configuration. Rather electrical power can also be generated thermoelectrically as described above as long as a first layer made of a first material with a relatively low Seebeck coefficient and relatively high thermal conductivity and a second layer made of a second material with a relatively high Seebeck coefficient and relatively low thermal conductivity are stacked alternately one upon the other. That is to say, the metal layer 20 and thermoelectric material layer 22 are only examples of such first and second layers, respectively.

<Implementation of Thermoelectric Generator Unit>

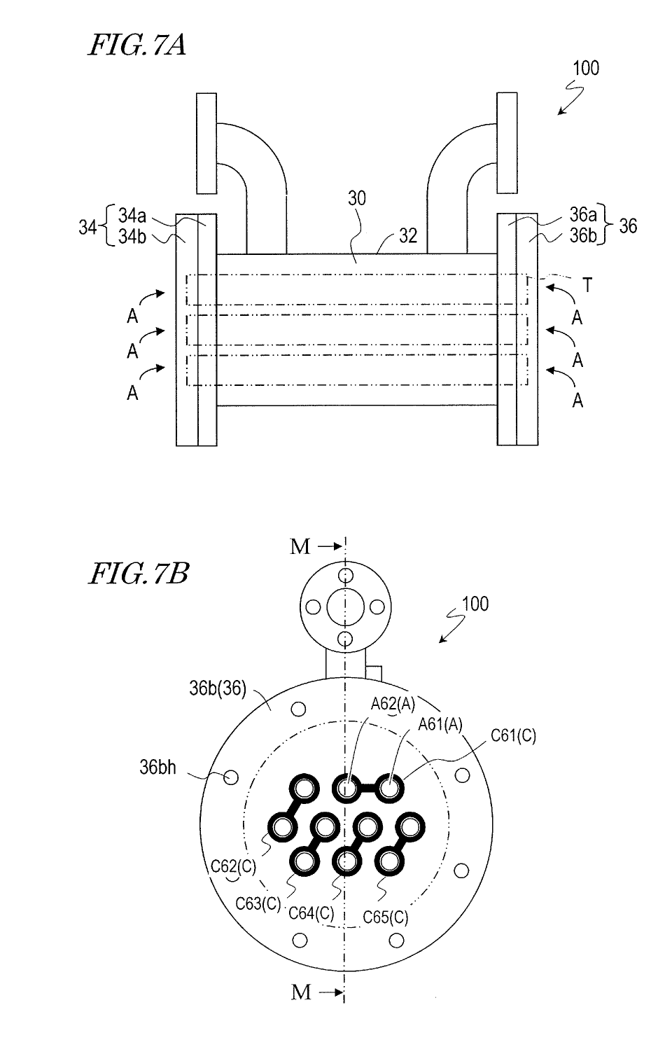

Next, look at FIGS. 7A and 7B. FIG. 7A is a front view illustrating an implementation of a thermoelectric generator unit that the thermoelectric generator system according to the present disclosure has, and FIG. 7B illustrates one of the side surfaces of the thermoelectric generator unit 100 (a right side view in this case). As shown in FIG. 7A, the thermoelectric generator unit 100 according to this implementation includes a number of tubular thermoelectric generators T which are arranged in parallel with each other and a container 30 which houses those tubular thermoelectric generators T inside. At a glance, such a structure looks like the “shell and tube structure” of a heat exchanger. In a heat exchanger, however, a number of tubes just function as pipelines to make fluid flow through and do not have to be electrically connected together.

As already described with reference to FIG. 4, a hot medium and a cold medium are supplied to the thermoelectric generator unit 100. The hot medium may be supplied into the respective internal flow paths of the tubular thermoelectric generators T1 to T10 through multiple openings A, for example. Meanwhile, the cold medium is supplied into the container 30 through a fluid inlet port 38a to be described later. As a result, a temperature difference is created between the outer and inner peripheral surfaces of each tubular thermoelectric generator T. In this case, in the thermoelectric generator unit 100, not only heat is exchanged between the hot and cold media but also electromotive force occurs in the axial direction in each of the tubular thermoelectric generators T1 to T10. As can be seen, a thermoelectric generator unit of the thermoelectric generator system according to the present disclosure performs thermoelectric generation using first and second heat transfer media at mutually different temperatures.

In this embodiment, the container 30 includes a cylindrical shell 32 which surrounds the tubular thermoelectric generators T and a pair of plates 34 and 36 which are arranged to close the open ends of the shell 32. In this example, the plates 34 and 36 are respectively fixed onto the left and right ends of the shell 32. Each of these plates 34 and 36 has multiple openings A into which respective tubular thermoelectric generators T are inserted. Both ends of an associated tubular thermoelectric generator T are inserted into each corresponding pair of openings A of the plates 34 and 36.

Just like the tube sheets of a shell and tube heat exchanger, these plates 34 and 36 have the function of supporting a plurality of tubes (i.e., the tubular thermoelectric generators T) so that these tubes are spatially separated from each other. However, as will be described in detail later, the plates 34 and 36 of this embodiment have an electrical connection capability that the tube sheets of a heat exchanger do not have.

In the example illustrated in FIG. 7A, the plate 34 includes a first plate portion 34a fixed to the shell 32 and a second plate portion 34b which is attached to the first plate portion 34a so as to be readily removable from the first plate portion 34a. Likewise, the plate 36 also includes a first plate portion 36a fixed to the shell 32 and a second plate portion 36b which is attached to the first plate portion 36a so as to be readily removable from the first plate portion 36a. The openings A in the plates 34 and 36 penetrate through, respectively, the first plate portions 34a and 36a and the second plate portions 34b and 36b, thus leaving the flow paths of the thermoelectric generation tubes T open to the exterior of the container 30.

Examples of materials to make the container 30 include metals such as stainless steel, HASTELLOY™ or INCONEL™. Examples of other materials to make the container 30 include polyvinyl chloride and acrylic resin. The shell 32 and the plates 34, 36 may be made of the same material or may be made of two different materials. If the shell 32 and the first plate portions 34a and 36a are made of metal(s), then the first plate portions 34a and 36a may be welded onto the shell 32. Or if flanges are provided at both ends of the shell 32, the first plate portions 34a and 36a may be fixed onto those flange portions.

Since some fluid (that is either the cold medium or hot medium) is introduced into the container 30 while the thermoelectric generator unit 100 is operating, the inside of the container 30 should be kept either airtight or watertight. As will be described later, each opening A of the plates 34, 36 is sealed to keep the inside of the container 30 either airtight or watertight once the ends of the tubular thermoelectric generator T have been inserted through the opening A. A structure in which no gap is left between the shell 32 and the plates 34, 36 and which is kept either airtight or watertight throughout the operation is realized.

As shown in FIG. 7B, ten openings A have been cut through the plate 36. Likewise, ten openings A have also been cut through the other plate 34. In the example illustrated in FIG. 7B, each opening A of the plate 34 and its associated opening A of the plate 36 are arranged mirror-symmetrically to each other, and ten lines which connect together the respective center points of ten pairs of associated openings A are parallel to each other. According to such a configuration, the respective tubular thermoelectric generators T may be supported parallel to each other through the pairs of associated openings A. Nevertheless, those tubular thermoelectric generators T do not have to be arranged parallel to each other inside the container 30 but may also be arranged either non-parallel or skew to each other.

As shown in FIG. 7B, the plate 36 has channels C, each of which has been formed to connect together at least two of the openings A cut through the plate 36 and will be sometimes hereinafter referred to as a “connection groove”. In the example illustrated in FIG. 7B, the channel C61 connects together openings A61 and A62. Each of the other channels C62 to C65 also connects together two associated ones of the openings A in the plate 36. As will be described later, an electrically conductive member is housed in each of these channels C61 to C65.

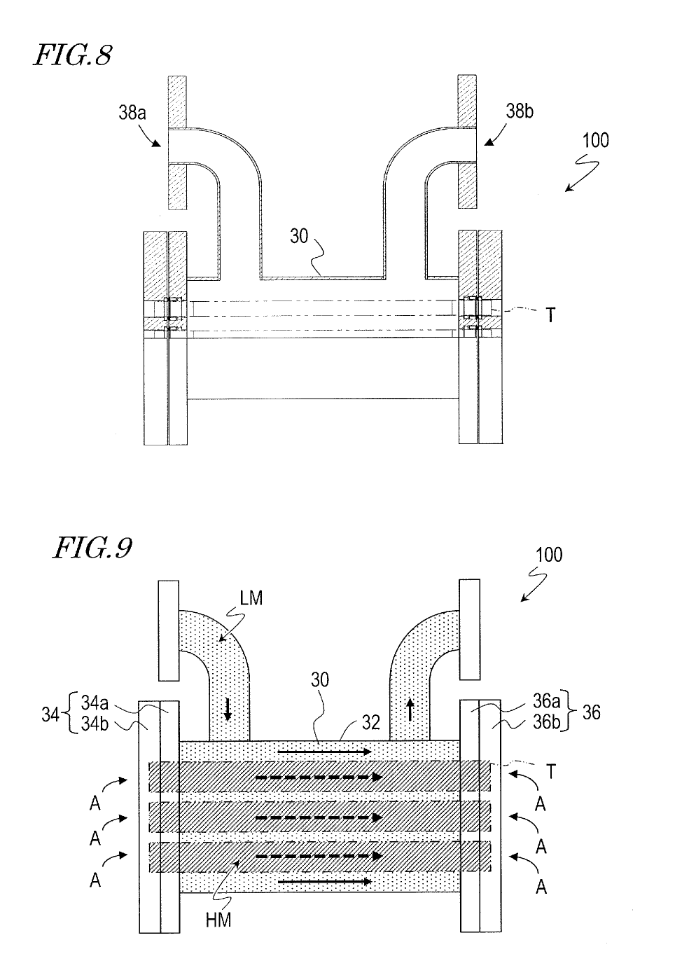

FIG. 8 illustrates a portion of a cross section of the thermoelectric generator unit 100 as viewed on the plane M-M shown in FIG. 7B. It should be noted that in FIG. 8, a cross section of the lower half of the shell 32 (i.e., the lower half of the container 30) is not shown but its front portion is shown instead. As shown in FIG. 8, the container 30 has a fluid inlet port 38a and a fluid outlet port 38b through which a fluid flows inside the container 30. In this thermoelectric generator unit 100, the fluid inlet and outlet ports 38a and 38b are arranged in the upper part of the container 30. However, the fluid inlet port 38a does not have to be arranged in the upper part of the container 30 but may also be arranged in the lower part of the container 30 as well. The same can be said about the fluid outlet port 38b. The fluid inlet and outlet ports 38a and 38b do not always have to be used as inlet and outlet for a fluid but may be inverted at regular or irregular intervals. That is to say, the fluid flowing direction does not have to be fixed. Also, although only one fluid inlet port 38a and only one fluid outlet port 38b are shown in FIG. 8, this is only an example, and more than one fluid inlet port 38a and/or more than one fluid outlet port 38b may be provided as well.

FIG. 9 schematically shows exemplary flow directions of the hot and cold media introduced into the thermoelectric generator unit 100. In the example shown in FIG. 9, a hot medium HM is supplied into the internal flow path of each of the tubular thermoelectric generators T1 to T10, while a cold medium LM is supplied into the container 30. In this example, the hot medium HM is introduced into the internal flow path of each tubular thermoelectric generator through the openings A cut through the plate 34. The hot medium HM introduced into the internal flow path of each tubular thermoelectric generator contacts with the inner peripheral surface of the tubular thermoelectric generator. On the other hand, the cold medium LM is introduced into the container 30 through the fluid inlet port 38a. The cold medium LM introduced into the container 30 contacts with the outer peripheral surface of each tubular thermoelectric generator.

In the example shown in FIG. 9, while flowing through the internal flow path of each tubular thermoelectric generator, the hot medium HM exchanges heat with the cold medium LM. The hot medium HM, of which the temperature has decreased through heat exchange with the cold medium LM, is discharged out of the thermoelectric generator unit 100 through the openings A of the plate 36. On the other hand, while flowing inside the container 30, the cold medium LM exchanges heat with the hot medium HM. The cold medium LM, of which the temperature has increased through heat exchange with the hot medium HM, is discharged out of the thermoelectric generator unit 100 through the fluid outlet port 38b. The flow directions of the hot and cold media HM and LM shown in FIG. 9 are only an example. One or both of the hot and cold media HM and LM may flow from the right to the left on the paper.

In one implementation, the hot medium HM (e.g., hot water) may be introduced into the flow path of each tubular thermoelectric generator T, and the cold medium LM (e.g., cooling water) may be introduced through the fluid inlet port 38a to fill the inside of the container 30 with the cold medium LM. Conversely, the cold medium LM (e.g., cooling water) may be introduced into the flow path of each tubular thermoelectric generator T, and the hot medium HM (e.g., hot water) may be introduced through the fluid inlet port 38a to fill the inside of the container 30 with the hot medium HM. In this manner, a temperature difference which is large enough to generate electric power can be created between the outer and inner peripheral surfaces 24 and 26 of each tubular thermoelectric generator T.

<Characteristics of Tubular Thermoelectric Generator>

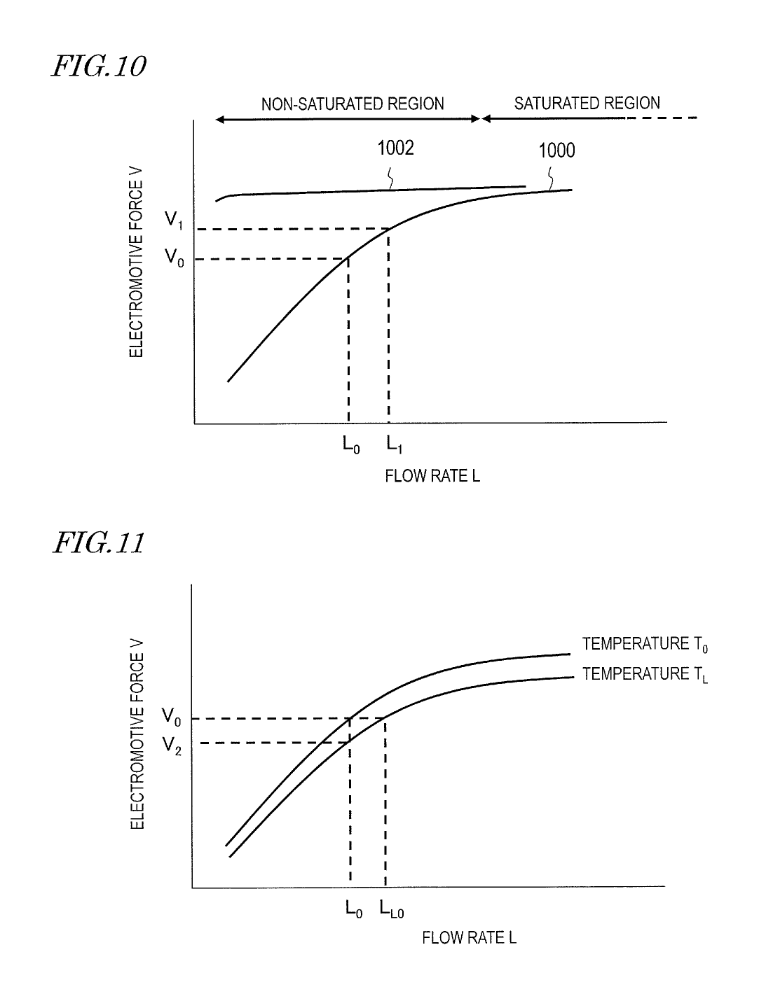

Next, it will be described with reference to FIGS. 10 and 11 how the electromotive force generated by a tubular thermoelectric generator changes with the flow rate of the heat transfer medium in an embodiment of the present disclosure.

FIG. 10 is a graph showing how the electromotive force V generated by the tubular thermoelectric generator changes with the flow rate L of a hot medium (at a temperature T) flowing through the thermoelectric generator unit. In this graph, plotted are a curve 1000 indicating typically how the electromotive force V generated by the tubular thermoelectric generator changes with the flow rate L of the hot medium (at a temperature T) and a curve 1002 indicating typically how the electromotive force V generated by a conventional Π-shaped thermoelectric generator changes with the flow rate L of the hot medium.

As shown in FIG. 10, the operation of the tubular thermoelectric generator is classified into a mode of operation in a “saturated region” in which the electromotive force V hardly changes with the flow rate L and a mode of operation in a “non-saturated region” in which the electromotive force V changes linearly with the flow rate L. In the non-saturated region mode, when the flow rate is L₀, the electromotive force is V₀. However, if the flow rate increases from L₀ to V₁, the electromotive force also increases from V₀ to V₁. Supposing the increases in flow rate L and electromotive force V are ΔL and ΔV, respectively, Δv/ΔL in the saturated region is much smaller than ΔV/ΔL in the non-saturated region. It is difficult to draw a boundary line definitely between the non-saturated region and the saturated region. For example, a range of the flow rate L in which ΔV/ΔL is less than 0.1 [V·min/L (volts·minutes per liter)] may be defined as the saturated region.

On the other hand, as indicated by the curve 1002, the electromotive force V depends much less heavily on the flow rate in the conventional Π-shaped thermoelectric generator. In other words, the Π-shaped thermoelectric generator operates in the saturated region mode but virtually does not operate in the non-saturated region mode. It will be described in detail later why such a difference is made in the mode of operation.

Next, look at FIG. 11. In the graph shown in FIG. 11, plotted are two curves indicating typically how the electromotive force V changes with the flow rate L in the same tubular thermoelectric generator when the temperature of the hot medium is T₀ and when the temperature of the hot medium is T_{L}, respectively. As can be seen from FIG. 11, if the temperature of the hot medium decreases from T₀ to T_{L} at a flow rate of L₀, the electromotive force decreases from V₀ to V₂. In the example shown in FIG. 11, if the flow rate is increased from L₀ to L_{L0} with the temperature of the hot medium maintained at T_{L}, the electromotive force increases from V₂ to V₀. In the non-saturated region mode, a control operation may be carried out so as to maintain the electromotive force V of the tubular thermoelectric generator at a target value by adjusting the flow rate L of the hot medium. Alternatively, a control operation may also be carried out so as to maintain the electromotive force V of the tubular thermoelectric generator at a target value by adjusting not only the flow rate of the hot medium but also the flow rate of the cold medium as well, instead of adjusting just the flow rate of the hot medium.

It should be noted that if the tubular thermoelectric generator is allowed to operate in the saturated region mode, the electromotive force V varies little even when the flow rate of the hot or cold medium changes. For that reason, if the heat transfer medium is supplied at a sufficiently high flow rate from the supply source of the hot or cold medium, the electrical power output level can be stabilized more easily by making the tubular thermoelectric generator operate in the saturated region in which the power output level is hardly affected by any variation in the flow rate of the heat transfer medium.

A tubular thermoelectric generator according to an embodiment of the present disclosure can operate in not only the saturated region mode but also the non-saturated region mode in which it is difficult for a conventional Π-shaped thermoelectric generator to operate. The reason will be described below.

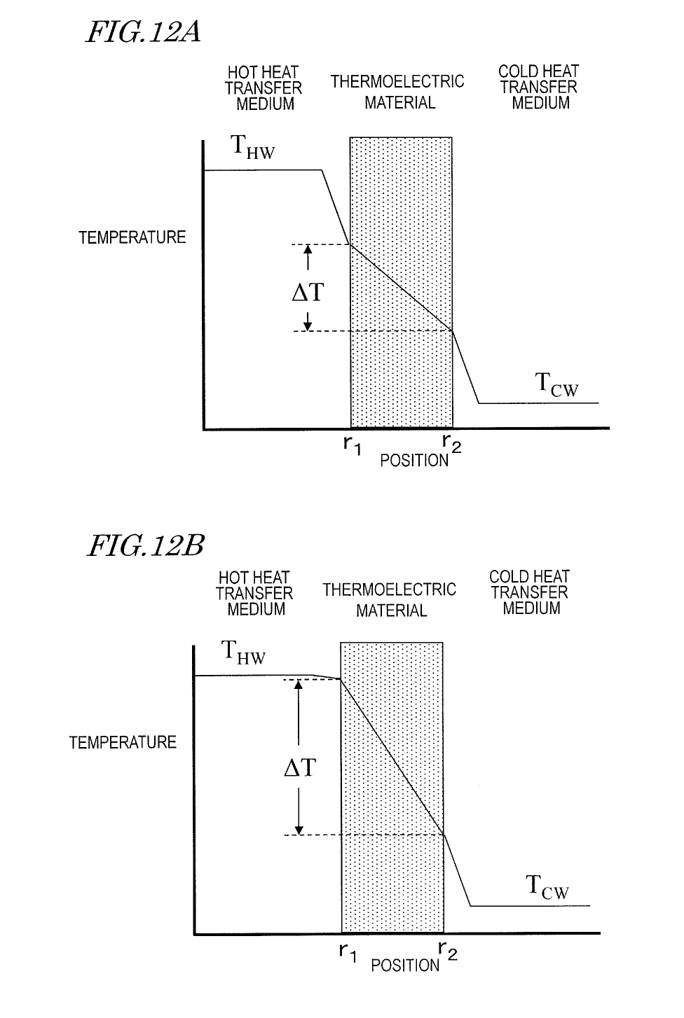

First of all, look at FIGS. 12A and 12B, which schematically show temperature distributions in the hot medium, a thermoelectric material portion of the tubular thermoelectric generator, and the cold medium. In FIGS. 12A and 12B, the abscissa indicates the radial position with respect to the center of the tubular thermoelectric generator as the origin and the ordinate indicates the temperature. The inner and outer peripheral surfaces of the body portion of the tubular thermoelectric generator are located at radial positions r1 and r2, respectively. The range between these radial positions r1 and r2 corresponds to the thermoelectric material portion of the tubular thermoelectric generator's body. The temperature distributions shown in FIGS. 12A and 12B are obtained when the flow rate of the hot medium is low and when the flow rate of the hot medium is high, respectively.

In FIGS. 12A and 12B, the temperatures of the hot and cold media are indicated approximately by T_{HW} and T_{CW}, respectively. In a thin region of the hot medium which is in contact with the inner peripheral surface of the tubular thermoelectric generator's body (which will be hereinafter referred to as a “high-temperature interfacial region”), the closer to the tubular thermoelectric generator's body, the more steeply the temperature of the hot medium falls from T_{HW}. Meanwhile, in a thin region of the cold medium which is in contact with the outer peripheral surface of the tubular thermoelectric generator's body (which will be hereinafter referred to as a “low-temperature interfacial region”), the closer to the tubular thermoelectric generator's body, the more steeply the temperature of the cold medium rises from T_{CW} The temperature difference created between the inner and outer peripheral surfaces of the tubular thermoelectric generator is indicated by ΔT. The electromotive force and electrical power generated (which will be hereinafter referred to as a “power output level”) increase as the temperature difference ΔT widens.

Heat flows from a high-temperature portion of the hot medium toward a low-temperature portion of the cold medium by way of the high-temperature interfacial region, the tubular thermoelectric generator's body, and the low-temperature interfacial region. “Thermal resistance” can be considered applied to this flow of heat. The thermal resistance corresponds to resistance on electric current. And the temperature will fall (corresponding to a voltage drop) where there is thermal resistance. In the present specification, the thermal resistances in the high-temperature interfacial region, tubular thermoelectric generator's body, and low-temperature interfacial region will be denoted herein by R_{H}, R_{D} and R_{C}, respectively. In that case, ΔT is represented by the following Equation (1):

$$Δ T = ( {T}_{HW} - {T}_{CW} ) \frac{{R}_{D}}{( {R}_{H} + {R}_{D} + {R}_{C} )} \qquad ( 1 )$$

In the tubular thermoelectric generator according to an embodiment of the present invention, a first type of layers made of a first material with high thermal conductivity (e.g., metal layers in this case) are arranged inclined with respect to the axial direction. Therefore, heat can be transferred more easily in the radial direction of the tubular thermoelectric generator and the thermal resistance R_{D} of the tubular thermoelectric generator's body is lower than that of the conventional Π-shaped thermoelectric generator.

In this case, the higher the flow rate of the hot medium, the lower the thermal resistance R_{H} in the high-temperature interfacial region gets. Likewise, the higher the flow rate of the cold medium, the lower the thermal resistance R_{C} in the low-temperature interfacial region gets. But the thermal resistance R_{D} of the tubular thermoelectric generator's body does not depend on the flow rates of the hot and cold media.

As can be seen from Equation (1), as the thermal resistances R_{H} and R_{C} are lowered by increasing the flow rates of the hot and cold media, ΔT gets closer to T_{HW}−T_{CW}. This means that the lower the thermal resistances R_{H} and R_{C}, the smaller the variation in temperature in the high-temperature and low-temperature interfacial regions.

The difference between the temperature distributions shown in FIGS. 12A and 12B is a difference in the degree of temperature variation in the high-temperature interfacial region. The temperature variation in the high-temperature interfacial region is relatively large in the example shown in FIG. 12A but relatively small in the example shown in FIG. 12B. This means that an increase in the flow rate of the hot medium causes a decrease in the thermal resistance R_{H} in the high-temperature interfacial region, thus increasing ΔT and making ΔT even closer to T_{HW}−T_{CW}. For instance, in the example shown in FIG. 10, if the flow rate increases from L₀ to L₁, the thermal resistance R_{H} falls and ΔT widens. As a result, the electromotive force increases from V₀ to V₁.

The same phenomenon arises even if the flow rate of the cold medium is increased. Also, if the flow rates of the hot and cold media are both increased, ΔT widens even more significantly. However, no matter how much the flow rate is increased, ΔT never exceeds T_{HW}−T_{CW}. This corresponds to the saturation in the relation between the electromotive force V and the flow rate L. That is to say, the saturated level of the electromotive force V is the magnitude of the electromotive force when ΔT is equal to T_{HW}−T_{CW}.

Next, it will be described why the relation between the electromotive force V and the flow rate L of the hot medium is substantially saturated with respect to the flow rate in the conventional Π-shaped thermoelectric generator as indicated by the curve 1002 in FIG. 10.

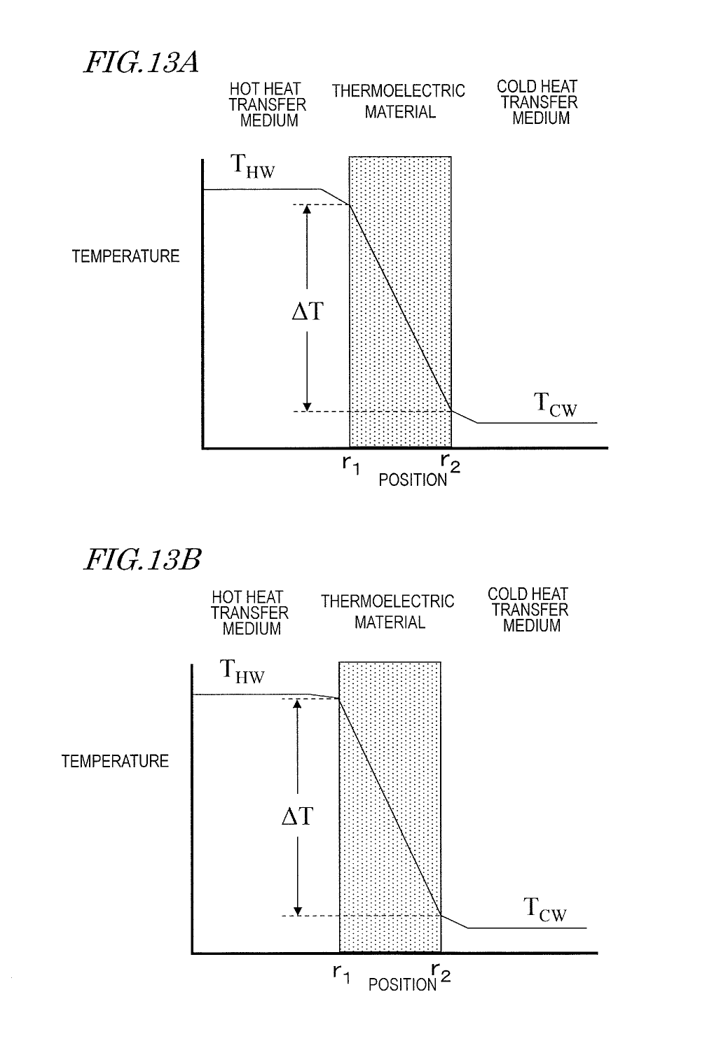

FIGS. 13A and 13B show two exemplary situations where the flow rates of the hot medium are low and high, respectively, in the conventional Π-shaped thermoelectric generator. In the temperature distributions of the Π-shaped thermoelectric generator, the abscissa of the graphs is not the “radial position” but just a distance. Nevertheless, the positions are indicated by using the same signs r1 and r2 as in FIGS. 12A and 12B so that the data shown in FIGS. 13A and 13B can be easily compared to the data shown in FIGS. 12A and 12B.

In the conventional Π-shaped thermoelectric generator, the thermal resistance R_{D} of the thermoelectric material is sufficiently greater than the thermal resistance R_{H} in the high-temperature interfacial region and the thermal resistance R_{C} in the low-temperature interfacial region. For this reason, as heat flows from the hot medium toward the cold medium, the temperature changes significantly in the thermoelectric material with relatively high thermal resistance. In other words, ΔT always has a value close to T_{HW}−T_{CW}, no matter whether the flow rate is high or low.

Equation (1) described above can be modified into the following Equation (2):

$$Δ T = ( {T}_{HW} - {T}_{CW} ) \frac{1}{\frac{{R}_{H}}{{R}_{D}} + 1 + \frac{{R}_{C}}{{R}_{D}}} \qquad ( 2 )$$

In the conventional Π-shaped thermoelectric generator, the thermal resistance R_{D} of its element structure is so high that the denominator of the fraction on the right side of this Equation (2) always has a value close to one, irrespective of the flow rate of the heat transfer medium. Also, the variations in the thermal resistance R_{H} in the high-temperature interfacial region and the thermal resistance R_{C} in the low-temperature interfacial region with the flow rate do not affect significantly ΔT. As can be seen from FIGS. 13A and 13B, even when the flow rate is low, ΔT also has a value close to T_{HW}−T_{CW}, and depends very little on the flow rate. Consequently, the characteristic represented by the curve 1002 shown in FIG. 10 is obtained.

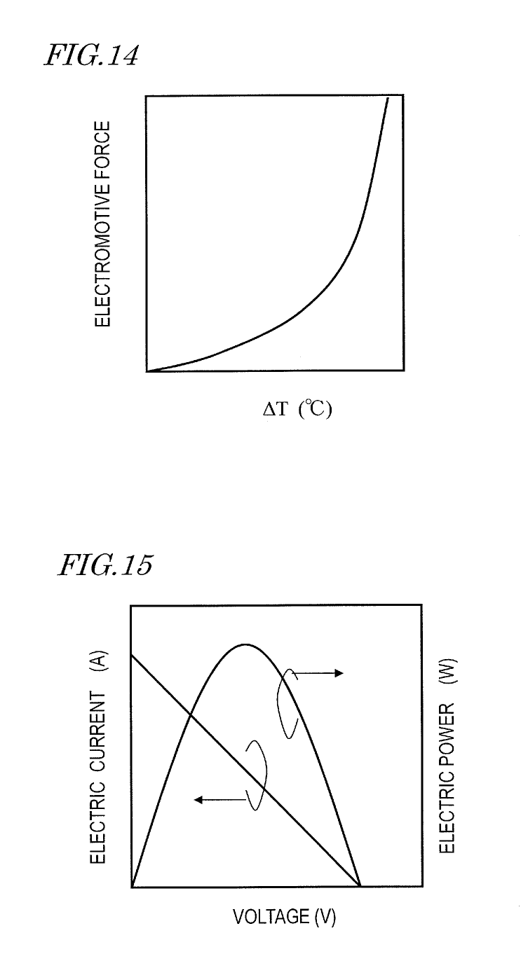

It should be noted that the relation between the electromotive force and ΔT may be as shown in FIG. 14, for example. The relation between the electric current flowing through the tubular thermoelectric generator and the potential difference between both ends of the tubular thermoelectric generator may be represented by the line shown in FIG. 15, and the potential difference dependence of the power output level may be represented by the parabola shown in FIG. 15. To maximize the power generation efficiency of the tubular thermoelectric generator, the amount of electric current flowing through the tubular thermoelectric generator may be adjusted by an external load circuit connected to the tubular thermoelectric generator.

<Variation in Power Output Level of Thermoelectric Generator System>

As can be seen easily from the foregoing description, a tubular thermoelectric generator according to this embodiment of the present disclosure has lower thermal resistance R_{D} than the conventional Π-shaped thermoelectric generator, and therefore, can operate in the non-saturated region mode. When the generator operates in the non-saturated region mode, the power output level changes easily as the flow rate of the hot or cold medium varies. For that reason, if there is a decrease in the flow rate of the medium supplied to the thermoelectric generator system according to this embodiment of the present disclosure, the power output level may change significantly. As shown in FIG. 14, the electromotive force is very sensitive to a variation in ΔT. That is why even if the flow rate decreases just slightly, the power output level may drop significantly.

In one embodiment, a thermoelectric generator system according to the present disclosure may be connected to a first supply source to supply a first heat transfer medium through a first flow path and to a second supply source to supply a second heat transfer medium through a second flow path, respectively. At least one of the rates at which the first and second heat transfer media are respectively supplied from the first and second supply sources may vary with time. In such an embodiment, a variation in the supply rate would lead to a variation in the flow rate of the first or second heat transfer medium flowing through the thermoelectric generator unit, unless any particular measure is taken.

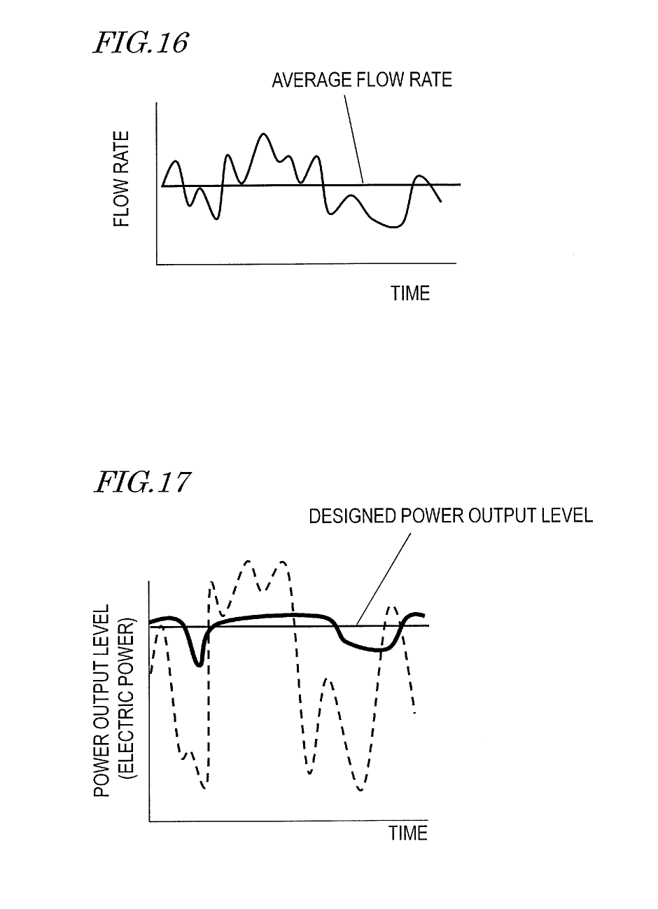

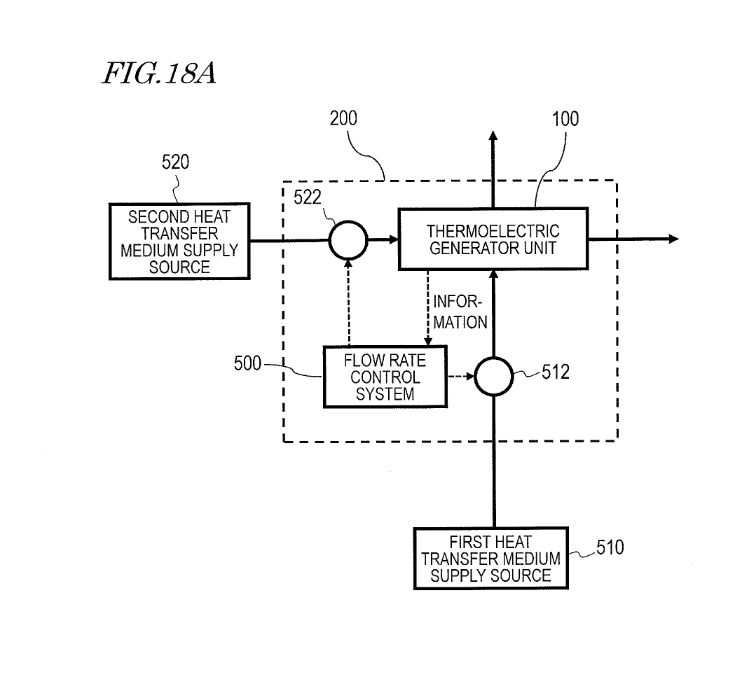

FIG. 16 schematically shows how the hot medium flowing through the thermoelectric generator unit may vary with time. As shown in FIG. 10, while the thermoelectric generator is operating in the non-saturated region mode, any variation in flow rate L will cause a variation in electromotive force V. Even while the thermoelectric generator is operating in the saturated region mode, a significant decrease in flow rate may cause a significant decrease in electromotive force.

FIG. 17 schematically shows how the power output level changes significantly (as indicated by the dotted curve) as the flow rate of the hot medium flowing through the thermoelectric generator unit may vary with time. The flow rate of the hot or cold medium may vary with time in the following situations. For example, if a thermoelectric generator system according to an embodiment of the present disclosure uses hot spring water as the hot medium, the flow rate of the hot spring water available for the thermoelectric generator system may vary significantly even on the same day, because the amount of hot spring water springing is not constant. On the other hand, even if a thermoelectric generator system according to an embodiment of the present disclosure uses high-temperature industrial wastewater drained from factories, the flow rate of the wastewater available for the thermoelectric generator system may vary significantly, because the daytime rate of operation of the factories is different from its nighttime rate.

A thermoelectric generator system according to an embodiment of the present disclosure can reduce such a variation in power output level as indicated by the solid curve in FIG. 17. That is to say, even when some medium, of which the flow rate is variable significantly on the same day, such as hot spring water or industrial wastewater, is used, a thermoelectric generator system according to an embodiment of the present disclosure can minimize such a variation in power output level that would be caused by a variation in the flow rate of the medium.

<Flow Rate Control in Thermoelectric Generator System>

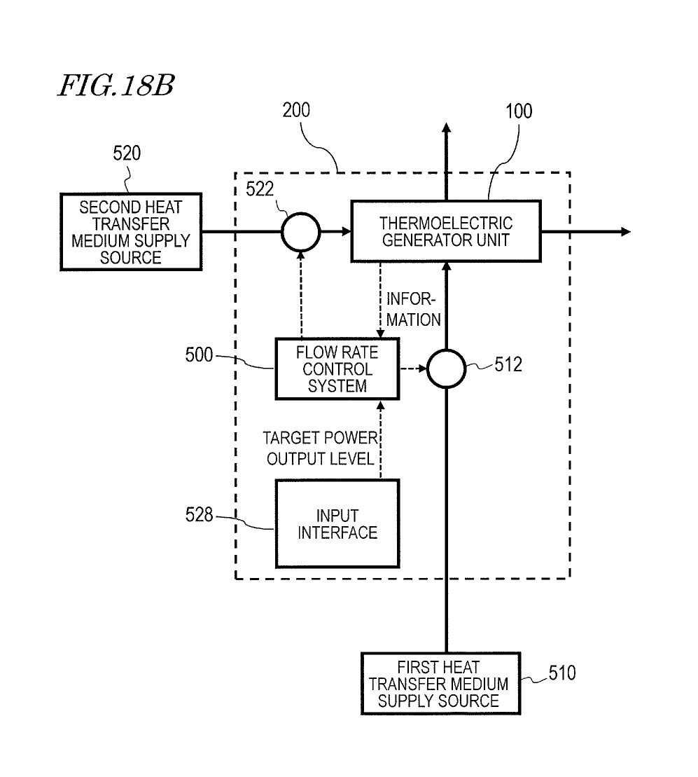

FIG. 18A is a block diagram illustrating an exemplary configuration for a thermoelectric generator system according to an embodiment of the present disclosure.

The thermoelectric generator system 200 in the example shown in FIG. 18A includes a thermoelectric generator unit 100 which performs thermoelectric generation using first and second heat transfer media at mutually different temperatures. The thermoelectric generator unit 100 includes tubular thermoelectric generators with the configuration described above.

This thermoelectric generator system 200 is connected to a first supply source 510 to supply a first heat transfer medium through a first flow path and to a second supply source 520 to supply a second heat transfer medium through a second flow path, respectively. At least one of the rates at which the first and second heat transfer media are respectively supplied from the first and second supply sources 510 and 520 may vary with time. This thermoelectric generator system 200 further includes a flow rate control system 500 which controls the flow rate of at least one of the first and second heat transfer media by reference to information about the operation condition of the thermoelectric generator system 200. In the example shown in FIG. 18A, a first flow rate control section 512 adjusts the flow rate of the first heat transfer medium flowing through the flow path of each tubular thermoelectric generator T and a second flow rate control section 522 adjusts the flow rate of the second heat transfer medium in contact with the outer peripheral surface of each tubular thermoelectric generator T.

This flow rate control system 500 may include a signal processor or computer which is configured to be provided with information about the operation condition of the thermoelectric generator system 200 and control the operation of the flow rate control sections 512 and 522 by reference to that information. The flow rate control system 500 may further include a storage device which stores a program or database to be used for controlling the flow rate. The storage device may be provided outside of the thermoelectric generator system 200. In that case, the storage device may be connected to the flow rate control system 500 over a digital network (not shown). In this manner, the flow rate control system 500 may be implemented as either a combination of hardware and software or a set of hardware components.

The operation of the flow rate control sections 512 and 522 may be controlled in accordance with a preset target power output level.

FIG. 18B is a block diagram illustrating another exemplary configuration for a thermoelectric generator system according to an embodiment of the present disclosure. As shown in FIG. 18B, the thermoelectric generator system 200 may further include an input interface 528 which is configured to get a target power output level.

In the example illustrated in FIG. 18B, the flow rate control system 500 controls the flow rate of at least one of the first and second heat transfer media in accordance with the target power output level. For example, the flow rate control system 500 may control the operation of the flow rate control sections 512 and 522 so that the power output level of the thermoelectric generator unit is not significantly different from the preset target power output level. In this case, the power output level of the thermoelectric generator unit may be used as a piece of information about the operation condition of the thermoelectric generator system 200.

The flow rate control system 500 may include a storage device to store the target power output level. The flow rate control system 500 may include a signal processor or computer which is configured to be receive information about the target power output level from the input interface 528 and control the operation of the flow rate control sections 512 and 522 by reference to the information provided about the target power output level. The target power output level is not a fixed value but may be changed (updated) as needed.

The target power output level is gotten by the input interface 528 with either wired or wireless method. The input interface 528 may further include a storage device to store information about the target power output level gotten. The input interface 528 may be configured to receive information from an external telecommunications terminal device such as a smartphone or may include an input device such as a touchscreen panel.

The target power output level may be entered by the owner of the thermoelectric generator system 200, a person who does maintenance of the thermoelectric generator system 200 or a power company employee. For example, the owner of the thermoelectric generator system 200 may enter his or her intended power output level as the target power output level through the input interface 528. Alternatively, the target power output level may also be entered by a power company employee via a smart grid, for example.

It should be noted that if the single thermoelectric generator system 200 includes a plurality of thermoelectric generator units 100, the single flow rate control system 500 may control the flow rates of the heat transfer media flowing through those multiple thermoelectric generator units 100. Or a plurality of flow rate control systems 500 may control the flow rates of heat transfer media flowing through those thermoelectric generator units 100 either independent of each other or in cooperation with each other.

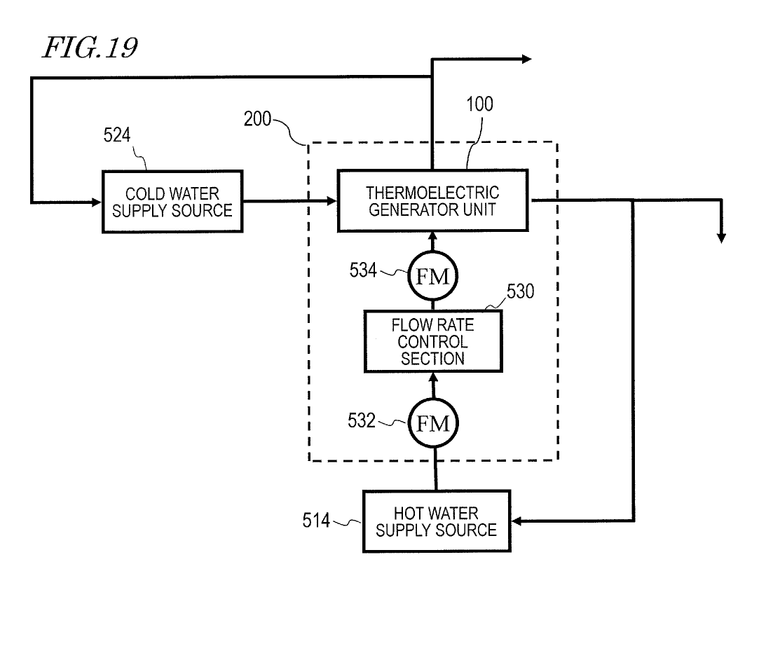

Next, a first exemplary basic configuration for the thermoelectric generator system 200 will be described with reference to FIG. 19.

The thermoelectric generator system 200 shown in FIG. 19 is connected to a hot water supply source 514 and a cold water supply source 524. Between the hot water supply source 514 and the thermoelectric generator unit 100, arranged are the first flowmeter 532, a flow rate control section 530 and the second flowmeter 534. In this example, the first flowmeter 532, the flow rate control section 530 and the second flowmeter 534 together form the flow rate control system 500 described above.

The first flowmeter 532 detects the flow rate of hot water flowing from the hot water supply source 514 into the flow rate control section 530. The second flowmeter 534 detects the flow rate of the hot water flowing from the flow rate control section 530 into the thermoelectric generator unit 100. The flow rate control section 530 adjusts the flow rate of the hot water so that the flow rate of the hot water flowing from the flow rate control section 530 into the thermoelectric generator unit 100 is kept constant at a preset value. The flow rate control section 530 is configured so as to minimize a variation in the flow rate of the hot water flowing from the flow rate control section 530 into the thermoelectric generator unit 100 even if the flow rate of the hot water flowing from the hot water supply source 514 into the flow rate control section 530 has varied. A specific exemplary configuration for the flow rate control section 530 will be described in detail later. The hot water that has passed through the thermoelectric generator unit 100 may be either supplied to a device which uses the hot water (not shown) or just drained as it is. Alternatively, this system may also be configured so that the hot water goes back to the hot water supply source 514 and then is heated by a heat source and circulated as hot water again. In the same way, the cold water that has passed through the thermoelectric generator unit 100 may be either supplied to a device which uses the cold water (not shown) or just drained as it is. Alternatively, this system may also be configured so that the cold water goes back to the cold water supply source 524 and then is cooled by a cold heat source and circulated as cold water again. Optionally, valves and/or check valves may be provided on the flow path or other flow paths (not shown) such as a branch or a bypass may be connected thereto. The same can be said about any of the other exemplary basic configurations of the thermoelectric generator system 200 to be described below.

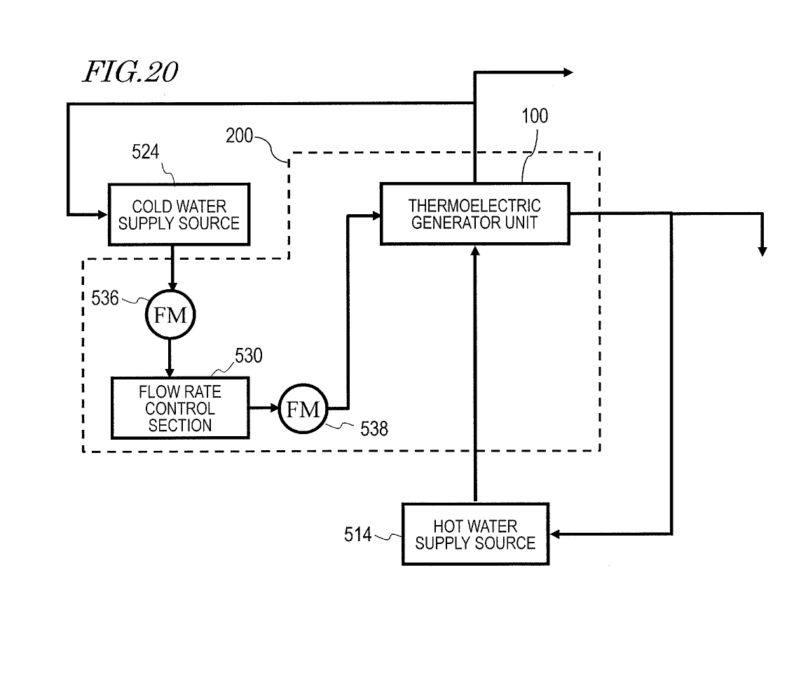

Next, a second exemplary basic configuration for the thermoelectric generator system 200 will be described with reference to FIG. 20.

The thermoelectric generator system 200 shown in FIG. 20 is also connected to the hot water supply source 514 and the cold water supply source 524. Between the cold water supply source 524 and the thermoelectric generator unit 100, arranged are the third flowmeter 536, the flow rate control section 530 and the fourth flowmeter 538. In this example, the third flowmeter 536, the flow rate control section 530 and the fourth flowmeter 538 together form the flow rate control system 500 described above.

The third flowmeter 536 detects the flow rate of cold water flowing from the cold water supply source 524 into the flow rate control section 530. The fourth flowmeter 538 detects the flow rate of the cold water flowing from the flow rate control section 530 into the thermoelectric generator unit 100. The flow rate control section 530 adjusts the flow rate of the cold water so that the flow rate of the cold water flowing from the flow rate control section 530 into the thermoelectric generator unit 100 is kept constant at a preset value. The flow rate control section 530 is configured so as to minimize a variation in the flow rate of the cold water flowing from the flow rate control section 530 into the thermoelectric generator unit 100 even if the flow rate of the cold water flowing from the cold water supply source 524 into the flow rate control section 530 has varied.

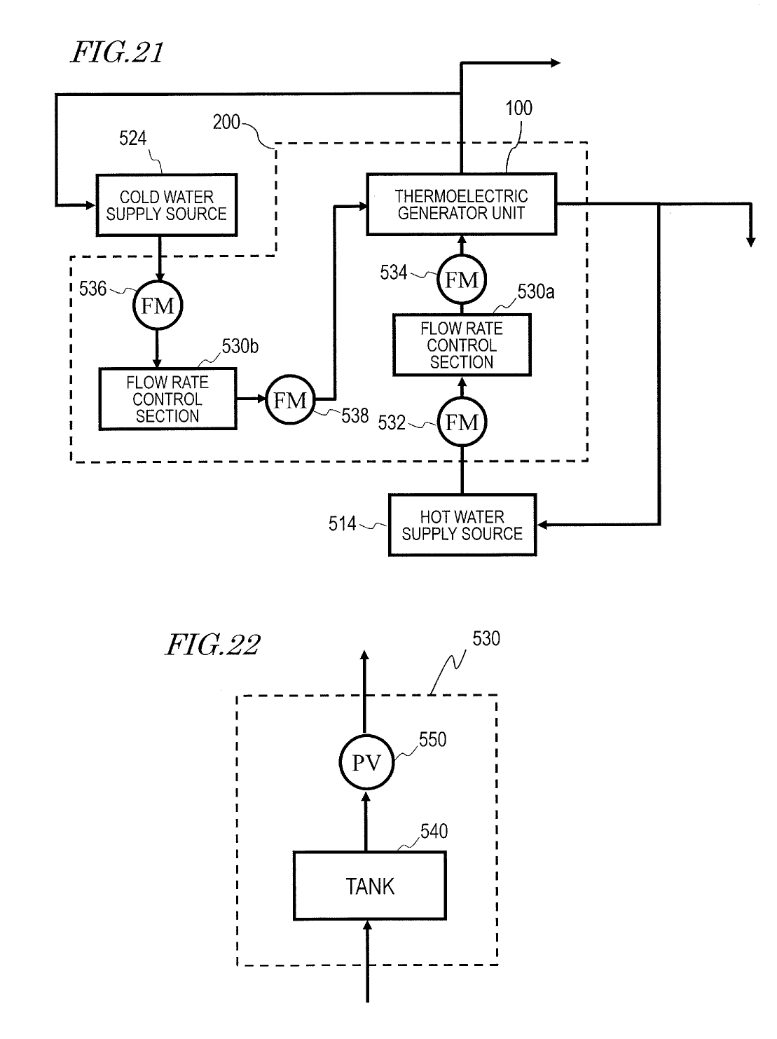

Next, a third exemplary basic configuration for the thermoelectric generator system 200 will be described with reference to FIG. 21.

The thermoelectric generator system 200 shown in FIG. 21 is also connected to the hot water supply source 514 and the cold water supply source 524. Between the hot water supply source 514 and the thermoelectric generator unit 100, arranged are the first flowmeter 532, a flow rate control section 530a and the second flowmeter 534. Also, between the cold water supply source 524 and the thermoelectric generator unit 100, arranged are the third flowmeter 536, a flow rate control section 530b and the fourth flowmeter 538. In this example, the first flowmeter 532, flow rate control section 530a, second flowmeter 534, third flowmeter 536, flow rate control section 530b and fourth flowmeter 538 together form the flow rate control system 500 described above. It will not be described how the flow rate control system 500 works in this example, because that can be seen easily from the foregoing description for the first and second exemplary basic configurations.

Next, an exemplary configuration for the flow rate control section 530 will be described with reference to FIGS. 22 through 27.

First of all, look at FIG. 22. The flow rate control section 530 shown in FIG. 22 includes a tank 540 to reserve a heat transfer medium temporarily and an adjustable flow control valve 550 through which the flow rate of the heat transfer medium is sent out of the tank 540 at a predetermined flow rate. Examples of the adjustable flow control valve 550 include a proportional solenoid valve and a gate valve, of which the valve opening can be adjusted. The tank 540 may operate as a storage container configured to store the first or second heat transfer medium temporarily. The adjustable flow control valve 550 may function as a regulator which regulates the flow rate of the heat transfer medium that flows out of the tank 540 into the thermoelectric generator unit 100 within a preset range.

By temporarily reserving the heat transfer medium that has flowed into the flow rate control section 530 in the tank 540 in this manner, the flow rate of the heat transfer medium to be supplied to the thermoelectric generator unit 100 can be adjusted into a different value from the flow rate of the heat transfer medium flowing into the flow rate control section 530. The flow rate of the heat transfer medium to be supplied to the thermoelectric generator unit 100 is controllable by reference to “information” about the operation condition of the thermoelectric generator system 200. In one embodiment, this “information” may include at least one of the power output level of the thermoelectric generator system 200 (which is at least one of the power, voltage and electric current), the temperature of the heat transfer medium, and the flow rate of the heat transfer medium. Optionally, the flow rate of the heat transfer medium to be supplied to the thermoelectric generator unit 100 may also be controlled based on the preset target power output level. Naturally, both the “information” about the operation condition of the thermoelectric generator system 200 and the preset target power output level may be used to control the flow rate of the heat transfer medium to be supplied to the thermoelectric generator unit 100.

The capacity of the tank 540 may be determined so that even if the flow rate of the heat transfer medium flowing into the flow rate control section 530 has decreased temporarily, the flow rate of the heat transfer medium flowing out of the flow rate control section 530 into the thermoelectric generator unit 100 can still be maintained within a target range. Suppose, as a simple example, a situation where the average flow rate of the heat transfer medium flowing from a heat transfer medium supply source into the flow rate control section 530 is L0 and the target flow rate of the heat transfer medium flowing into the thermoelectric generator unit 100 is L0, too. Also, suppose in such a situation, the flow rate of the heat transfer medium flowing out of its supply source into the flow rate control section 530 has decreased temporarily by ΔL and the period of decrease is estimated to be Δt. The unit of the flow rate is [L/min (liters/minute)] and the unit of the decrease period is [min (minutes)]. The capacity of the tank 540 may be set to be equal to or greater than ΔL×Δt [L], for example. As long as the heat transfer medium is stored in the tank 540 to ΔL×Δt [L] or more, even if the flow rate of the heat transfer medium flowing into the flow rate control section 530 has decreased by ΔL on average in the period Δt, the flow rate of the heat transfer medium flowing into the thermoelectric generator unit 100 does not have to be decreased from the target value L0 in the meantime.

The capacity of the tank 540 may be estimated based on experimental data on a variation in the flow rate of the heat transfer medium supplied from the heat transfer medium supply source into the thermoelectric generator system 200. For example, a variation with time in the flow rate of the first heat transfer medium supplied from the first heat transfer medium supply source 510 shown in FIG. 18A into the thermoelectric generator system 200 may be measured in advance and the value of ΔL×Δt may be determined based on the pattern of that variation with time.

In this case, the larger the capacity of the tank 540, the more important the heat insulation property and heat retaining property of the tank 540 becomes. The tank 540 may be made of a heat insulator, for example. Also, a sensor such as a thermometer may be provided inside the tank 540. By sensing the temperature of the heat transfer medium in the tank 540 using such a sensor, the difference between the temperature sensed and the preset temperature of the heat transfer medium flowing into the thermoelectric generator unit 100 can be calculated. And the flow rate control section 530 may be configured to make a part of the heat transfer medium in the tank 540 go back toward the heat transfer medium supply source if that difference increases to exceed a predetermined range (preset range).

Optionally, when the water starts to be reserved in the tank 540 for example, the water may be poured into, and drained from, the tank 540 repeatedly until the temperature difference falls within the preset range described above.

In one embodiment, the thermoelectric generator system 200 includes a database which stores data on how the power output level changes with the operation condition (such as the flow rate and temperature). By reference to this database with at least one of the actually measured values of various parameters including power, voltage, electric current, heat transfer medium's flow rate and heat transfer medium's temperature, the best operation condition can be obtained and the flow rate can be controlled.

Next, another exemplary configuration for the flow rate control section 530 will be described.

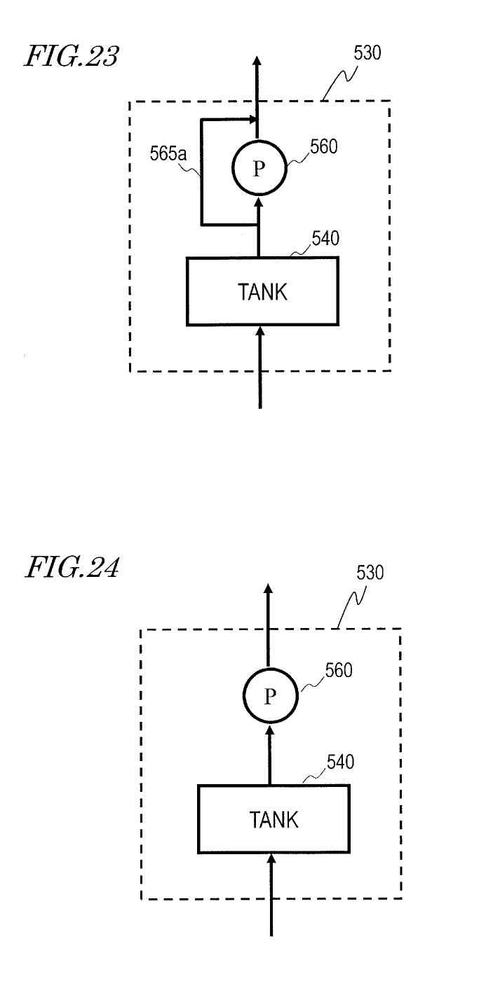

In the example shown in FIG. 23, an auxiliary pump 560 and a bypass flow path 565a are connected parallel with each other to the output of the tank 540. In the illustrated example, the auxiliary pump 560 is usually not working to keep the flow path on the auxiliary pump 560 side closed. That is to say, the flow rate of the heat transfer medium flowing into the thermoelectric generator unit 100 is regulated by an adjustable flow control valve (not shown) provided on the bypass flow path 565a. The auxiliary pump 560 is started unless the flow rate of the heat transfer medium flowing into the thermoelectric generator unit 100 reaches the target value even if the flow control valve provided on the bypass flow path 565a is fully opened. In this manner, the flow rate of the heat transfer medium supplied from the tank 540 to the thermoelectric generator unit 100 can be increased.

On the other hand, in the example shown in FIG. 24, the adjustable metering pump 560 is connected in series to the output of the tank 540. The adjustable metering pump 560 can work to regulate the flow rate of the heat transfer medium supplied from the tank 540 into the thermoelectric generator unit 100.

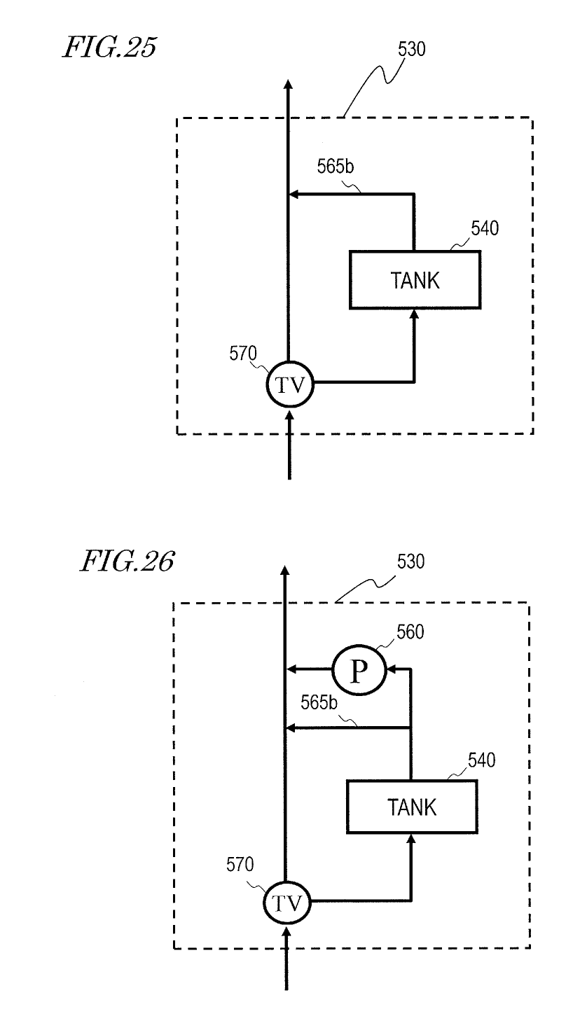

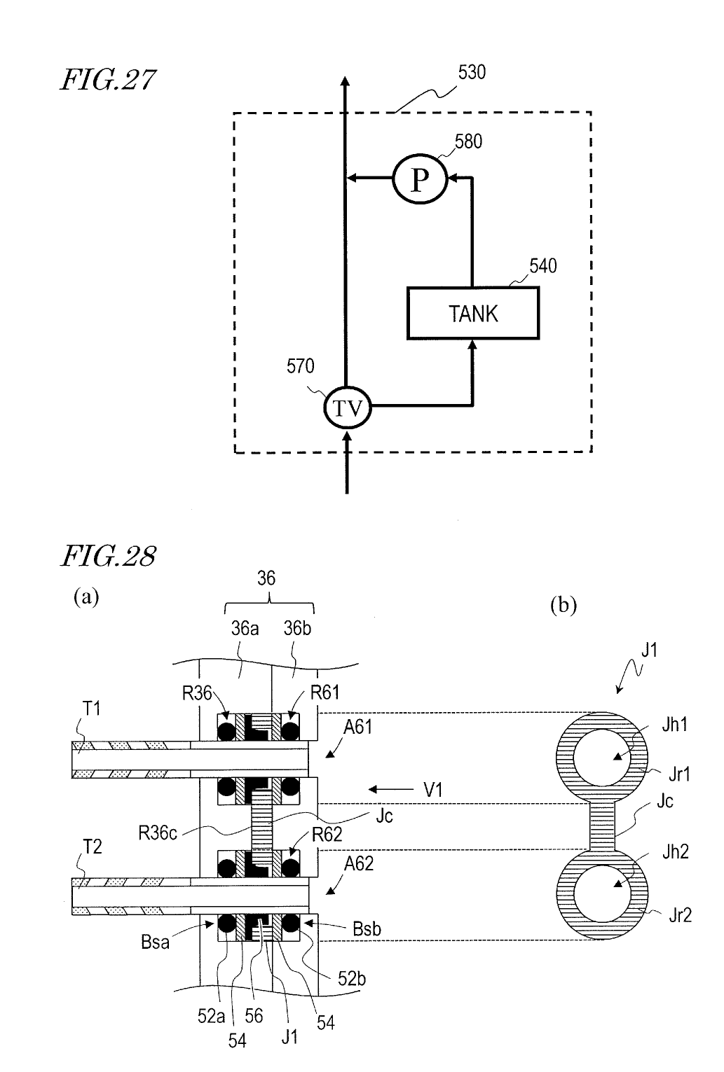

In the example shown in FIG. 25, the tank 540 is connected to a middle of a bypass flow path 565b which is branched by a three-way valve 570 that can change its valve opening. By adjusting the valve opening of the three-way valve 570, the flow rate of the heat transfer medium flowing into the flow rate control section 530 can be controlled so that the heat transfer medium is distributed to the thermoelectric generator unit 100 and the tank 540. If the flow rate of the heat transfer medium flowing into the flow rate control section 530 is greater than the target flow rate of the heat transfer medium supplied to the thermoelectric generator unit 100, the extra heat transfer medium can be forwarded to the tank 540. Conversely, if the flow rate of the heat transfer medium flowing into the flow rate control section 530 is less than the target flow rate of the heat transfer medium supplied to the thermoelectric generator unit 100, the heat transfer medium may also be supplied additionally from the tank 540 to the thermoelectric generator unit 100. On the bypass flow path 565b which connects the output of the tank 540 to the thermoelectric generator unit 100, a valve, a pump and other members for regulating the flow rate of the heat transfer medium flowing out of the tank 540 may be provided. Optionally, the three-way valve 570 may be replaced with two two-way valves. In that case, by switching the opened and closed states of those two valves with time, the two valves can perform the same function as the three-way valve 570. FIG. 26 is a modified example of the configuration of FIG. 25 and illustrates a configuration in which an auxiliary pump 560 and a bypass flow path 565b are connected parallel with each other to the output of the tank 540. Meanwhile, FIG. 27 illustrates an example in which an adjustable metering pump 580 is connected to the output of the tank 540 in place of the auxiliary pump 560 in the example shown in FIG. 26.

As described above, the tank 540 may be connected in various manners. The point is to use the heat transfer medium that is temporarily stored in the tank 540 when regulating the flow rate of the heat transfer medium to be supplied to the thermoelectric generator unit 100. Thus, any specific configuration may be adopted to connect the tank 540.

Next, exemplary specific configurations for the thermoelectric generator unit will be described.

<Implementations of Sealing from Fluids and Electrical Connection Between Tubular Thermoelectric Generators>

Portion (a) of FIG. 28 schematically illustrates a partial cross-sectional view of the plate 36. Specifically, portion (a) of FIG. 28 schematically illustrates a cross section of the plate 36 as viewed on a plane including the respective center axes of both of two tubular thermoelectric generators T1 and T2. More specifically, portion (a) of FIG. 28 illustrates the structure of openings A61 and A62 of multiple openings A that the plate 36 has and a region surrounding them. Portion (b) of FIG. 28 schematically illustrates the appearance of an electrically conductive member J1 as viewed in the direction indicated by the arrow V1 in portion (a) of FIG. 28. This electrically conductive member J1 has two through holes Jh1 and Jh2. In detail, this electrically conductive member J1 includes a first ring portion Jr1 with the through hole Jh1, a second ring portion Jr2 with the through hole Jh2, and a connecting portion Jc to connect these two ring portions Jr1 and Jr2 together.

As shown in portion (a) of FIG. 28, one end of the tubular thermoelectric generator T1 (on the second electrode side) is inserted into the opening A61 of the plate 36 and one end of the tubular thermoelectric generator T2 (on the first electrode side) is inserted into the opening A62. In this state, those ends of the tubular thermoelectric generators T1 and T2 are respectively inserted into the through holes Jh1 and Jh2 of the electrically conductive member J1. That end of the tubular thermoelectric generator T1 (on the second electrode side) and that of the tubular thermoelectric generator T2 (on the first electrode side) are electrically connected together via this electrically conductive member J1. In the present specification, an electrically conductive member to connect two tubular thermoelectric generators electrically together will be hereinafter referred to as a “connection plate”.

It should be noted that the first and second ring portions Jr1 and Jr2 do not have to have an annular shape. As long as electrical connection is established between the tubular thermoelectric generators, the through hole Jh1 or Jh2 may also have a circular, elliptical or polygonal shape as well. For example, the shape of the through hole Jh1 or Jh2 may be different from the cross-sectional shape of the first or second electrode E1 or E2 as viewed on a plane that intersects with the axial direction at right angles. In the present specification, the “ring” shape includes not only an annular shape but other shapes as well.

In the example illustrated in portion (a) of FIG. 28, the first plate portion 36a has a recess R36 which has been cut for the openings A61 and A62. This recess R36 includes a groove portion R36c to connect the openings A61 and A62 together. The connecting portion Jc of the electrically conductive member J1 is located in this groove portion R36c. On the other hand, recesses R61 and R62 have been cut in the second plate portion 36b for the openings A61 and A62, respectively. In this example, various members to establish sealing and electrical connection are arranged inside the space formed by these recesses R36, R61 and R62. That space forms a channel C61 to house the electrically conductive member J1 and the openings A61 and A62 are connected together via the channel C61.

In the example illustrated in portion (a) of FIG. 28, not only the electrically conductive member J1 but also a first O-ring 52a, washers 54, an electrically conductive ring member 56 and a second O-ring 52b are housed in the channel C61. The respective ends of the tubular thermoelectric generators T1 and T2 go through the holes of these members. The first O-ring 52a arranged closest to the shell 32 of the container 30 is in contact with the seating surface Bsa that has been formed in the first plate portion 36a and establishes sealing so as to prevent a fluid that has been supplied into the shell 32 from entering the channel C61. On the other hand, the second O-ring 52b arranged most distant from the shell 32 of the container 30 is in contact with a seating surface Bsb that has been formed in the second plate portion 36b and establishes sealing so as to prevent a fluid located outside of the second plate portion 36b from entering the channel C61.

The O-rings 52a and 52b are annular seal members with an O (i.e., circular) cross section. The O-rings 52a and 52b may be made of rubber, metal or plastic, for example, and have the function of preventing a fluid from leaking out, or flowing into, through a gap between the members. In portion (a) of FIG. 28, there is a space which communicates with the flow paths of the respective tubular thermoelectric generators T on the right-hand side of the second plate portion 36b and there is a fluid (the hot or cold medium in this example) in that space. According to this embodiment, by using the members shown in FIG. 28, electrical connection between the tubular thermoelectric generators T and sealing from the fluid (the hot and cold media) are established. The structure and function of the electrically conductive ring member 56 will be described in detail later.

The same members as the ones described for the plate 36 are provided for the plate 34, too. Although the respective openings A of the plates 34 and 36 are arranged mirror symmetrically, the groove portions connecting any two openings A together on the plate 34 are not arranged mirror symmetrically with the groove portions connecting any two openings A together on the plate 36. If the arrangement patterns of the electrically conductive members to electrically connect the tubular thermoelectric generators T together on the plates 34 and 36, were mirror symmetric to each other, then those tubular thermoelectric generators T could not be connected together in series.

If a plate (such as the plate 36) fixed onto the shell 32 includes first and second plate portions (36a and 36b) as in this embodiment, each of the multiple openings A cut through the first plate portion (36a) has a first seating surface (Bsa) associated therewith to receive the first O-ring 52a, and each of the multiple openings A cut through the second plate portion (36b) has a second seating surface (Bsb) to receive the second O-ring 52b. However, the plates 34 and 36 do not need to have the configuration shown in FIG. 28 and the plate 36 does not have to be divided into the first and second plate portions 36a and 36b, either. If the electrically conductive member J1 is pressed by another member instead of the second plate portion 36b, the respective first O-rings 52a press against the first seating surface (Bsa) to establish sealing, too.

In the example shown in portion (a) of FIG. 28, the electrically conductive ring member 56 is interposed between the tubular thermoelectric generator T1 and the electrically conductive member J1. Likewise, another electrically conductive ring member 56 is interposed between the tubular thermoelectric generator T2 and the electrically conductive member J1, too.

The electrically conductive member J1 is typically made of a metal. Examples of materials to make the electrically conductive member J1 include copper (oxygen-free copper), brass and aluminum. The material may be plated with nickel or tin for anticorrosion purposes. As long as electrical connection is established between the electrically conductive member J (e.g., J1 in this example) and the tubular thermoelectric generators T (e.g., T1 and T2 in this example) inserted into the two through holes of the electrically conductive member J (e.g., Jh1 and Jh2 in this example), the electrically conductive member J may be partially coated with an insulator. That is to say, the electrically conductive member J may include a body made of a metallic material and an insulating coating which covers the surface of the body at least partially. The insulating coating may be made of a resin such as TEFLON™, for example. If the body of the electrically conductive member J is made of aluminum, the surface may be partially coated with an oxide skin as an insulating coating.

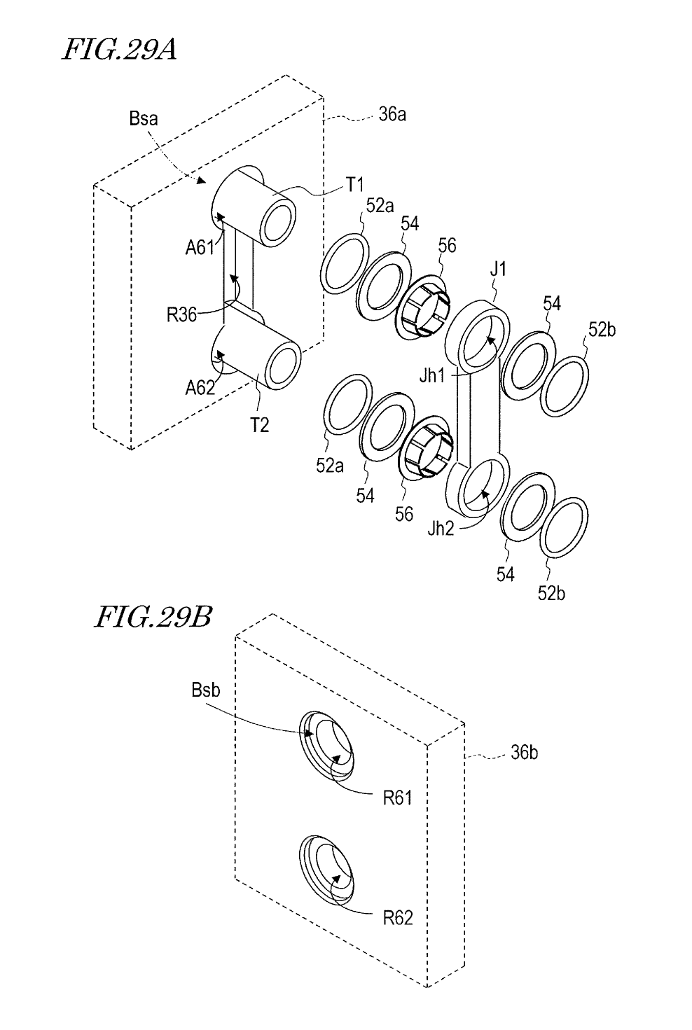

FIG. 29A is an exploded perspective view schematically illustrating the channel C61 to house the electrically conductive member J1 and its vicinity. As shown in FIG. 29A, the first O-rings 52a, electrically conductive ring members 56, electrically conductive member J1 and second O-rings 52b are inserted into the openings A61 and A62 from outside of the container 30. In this example, washers 54 are arranged between the first O-rings 52a and the electrically conductive ring members 56. Washers 54 may also be arranged between the electrically conductive member J1 and the second O-rings 52b. The washers 54 are inserted between the flat portions 56f of the electrically conductive ring members 56 to be described later and the O-rings 52a (or 52b).

FIG. 29B illustrates a portion of the sealing surface of the second plate portion 36b (i.e., the surface that faces the first plate portion 36a) associated with the openings A61 and A62. As described above, the openings A61 and A62 of the second plate portion 36b each have a seating surface Bsb to receive the second O-ring 52b. That is why if the respective sealing surfaces of the first and second plate portions 36a and 36b are arranged to face each other and fastened together by flange connection, for example, the first O-rings 52a in the first plate portion 36a can be pressed against the seating surfaces Bsa. More specifically, the second seating surfaces Bsb press the first O-rings 52a against the seating surfaces Bsa through the second O-rings 52b, electrically conductive member J1 and electrically conductive ring members 56. In this manner, the electrically conductive member J1 can be sealed from the hot and cold media.

If the first and second plate portions 36a and 36b are made of an electrically conductive material such as a metal, then the sealing surfaces of the first and second plate portions 36a and 36b may be coated with an insulator material. Parts of the first and second plate portions 36a and 36b to contact with the electrically conductive member J during operation may be coated with an insulator so as to be electrically insulated from the electrically conductive member J. In one implementation, the sealing surfaces of the first and second plate portions 36a and 36b may be sprayed and coated with a fluoroethylene resin.

<Detailed Configuration for Electrically Conductive Ring Members>

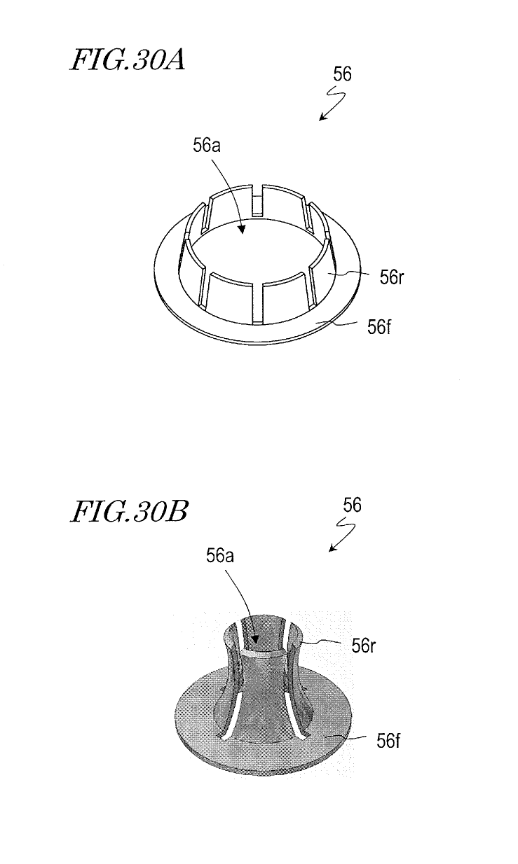

A detailed configuration for the electrically conductive ring members 56 will be described with reference to FIGS. 30A and 30B.

FIG. 30A is a perspective view illustrating an exemplary shape of a single electrically conductive ring member 56. The electrically conductive ring member 56 shown in FIG. 30A includes a ringlike flat portion 56f and a plurality of elastic portions 56r. The flat portion 56f has a through hole 56a. Those elastic portions 56r project from around the periphery of the through hole 56a of the flat portion 56f and are biased toward the center of the through hole 56a with elastic force. Such an electrically conductive ring member 56 can be made easily by patterning a single metallic plate (with a thickness of 0.1 mm to a few mm, for example). Likewise, the electrically conductive members J can also be made easily by patterning a single metallic plate (with a thickness of 0.1 mm to a few mm, for example).

An end (on the first or second electrode side) of an associated tubular thermoelectric generator T is inserted into the through hole 56a of each electrically conductive ring member 56. That is why the shape and size of the through hole 56a of the ringlike flat portion 56f are designed so as to match the shape and size of the outer peripheral surface of that end (on the first or second electrode side) of the tubular thermoelectric generator T.

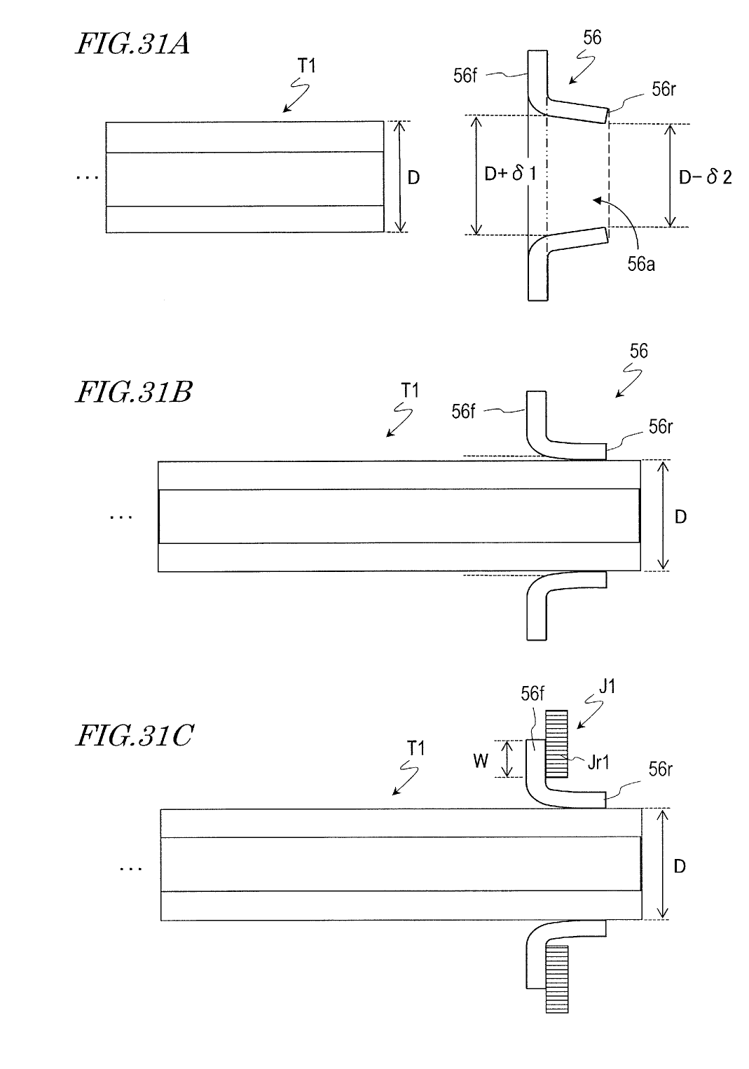

Next, the shape of the electrically conductive ring member 56 will be described in further detail with reference to FIG. 31. FIG. 31A is a cross-sectional view schematically illustrating portions of the electrically conductive ring member 56 and tubular thermoelectric generator T1. FIG. 31B is a cross-sectional view schematically illustrating a state where an end of the tubular thermoelectric generator T1 has been inserted into the electrically conductive ring member 56. And FIG. 31C is a cross-sectional view schematically illustrating a state where an end of the tubular thermoelectric generator T1 has been inserted into the respective through holes of the electrically conductive ring member 56 and electrically conductive member J1. The cross sections illustrated in FIGS. 31A, 31B and 31C are viewed on a plane including the axis (i.e., the center axis) of the tubular thermoelectric generator T1.

Suppose the outer peripheral surface of the tubular thermoelectric generator T1 at that end (on the first or second electrode side) is a circular cylinder with a diameter D as shown in FIG. 31A. In that case, the through hole 56a of the electrically conductive ring member 56 is formed in a circular shape with a diameter D+δ1 (where δ1>1) so as to pass the end of the tubular thermoelectric generator T1. On the other hand, the respective elastic portions 56r have been formed so that biasing force is applied toward the center of the through hole 56a. The respective elastic portions 56r may be formed so as to be tilted toward the center of the through hole 56a as shown in FIG. 31A. That is to say, the elastic portions 56r have been shaped so as to be circumscribed with the outer peripheral surface of a circular cylinder, of which a cross section has a diameter that is smaller than D (and that is represented by D−δ2 (where δ2>0)) unless any external force is applied.

D+δ1>D>D−δ2 is satisfied. That is why when the end of the tubular thermoelectric generator T1 is inserted into the through hole 56a, the respective elastic portions 56r are brought into physical contact with the outer peripheral surface at the end of the tubular thermoelectric generator T1 as shown in FIG. 31B. In this case, since elastic force is applied to the respective elastic portions 56r toward the center of the through hole 56a, the respective elastic portions 56r press the outer peripheral surface at the end of the tubular thermoelectric generator T1 with the elastic force. In this manner, the outer peripheral surface of the tubular thermoelectric generator T1 inserted into the through hole 56a establishes stabilized physical and electrical contact with those elastic portions 56r.

Next, look at FIG. 31C. Inside the opening A cut through the plate 34, 36, the electrically conductive member J contacts with the flat portion 56f of the electrically conductive ring member 56. More specifically, when the end of the tubular thermoelectric generator T1 is inserted into the electrically conductive ring member 56 and electrically conductive member J1, the surface of the flat portion 56f of the electrically conductive ring member 56 contacts with the surface of the ring portion Jr1 of the electrically conductive member J1 as shown in FIG. 31C. As can be seen, in this embodiment, the electrically conductive ring member 56 and the electrically conductive member J1 are electrically connected together by bringing their planes into contact with each other. Since the electrically conductive ring member 56 and the electrically conductive member J1 contact with each other on their planes, a contact area which is large enough to make the electric current generated in the tubular thermoelectric generator T1 flow can be secured. The width W of the flat portion 56f is set appropriately to secure a contact area which is large enough to make the electric current generated in the tubular thermoelectric generator T1 flow. As long as a contact area can be secured between the electrically conductive ring member 56 and the electrically conductive member J1, either the surface of the flat portion 56f or the surface of the ring portion Jr1 of the electrically conductive member J1 may have some unevenness. For example, an even larger area of contact can be secured by making the surface of the ring portion Jr1 of the electrically conductive member J1 have an embossed pattern matching the one on the surface of the flat portion 56f.

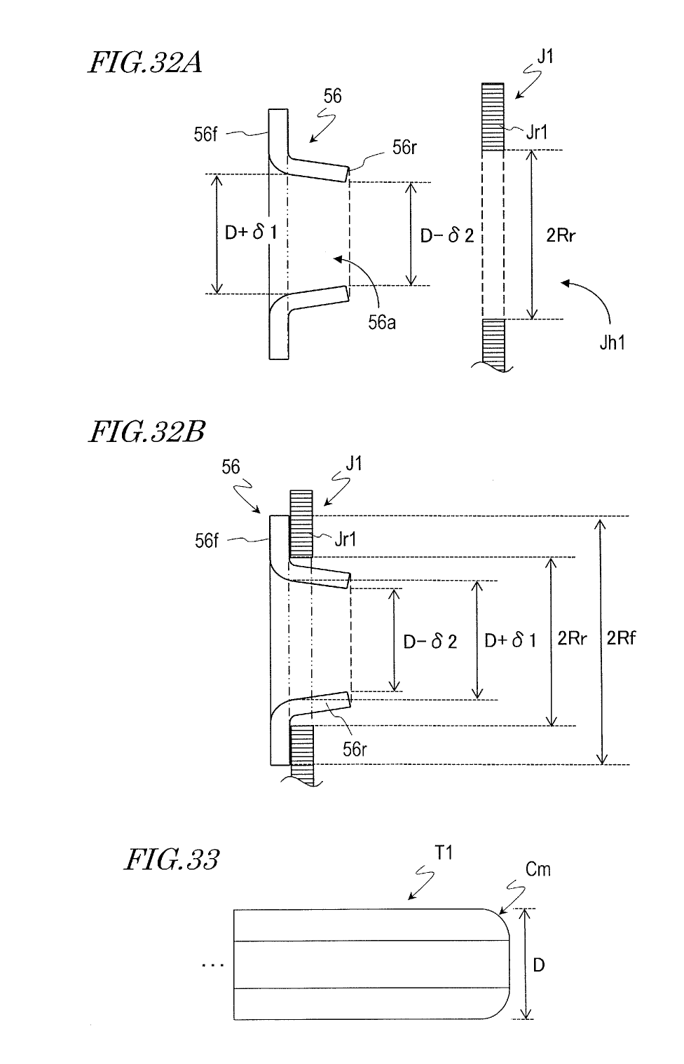

Next, look at FIGS. 32A and 32B. FIG. 32A is a cross-sectional view schematically illustrating the electrically conductive ring member 56 and a portion of the electrically conductive member J1. FIG. 32B is a cross-sectional view schematically illustrating a state where the elastic portions 56r of the electrically conductive ring member 56 have been inserted into the through hole Jh1 of the electrically conductive member J1. The cross sections shown in FIGS. 32A and 32B are obtained by viewing the electrically conductive ring member 56 and the electrically conductive member J1 on a plane including the axis (center axis) of the tubular thermoelectric generator T1.

If the diameter of the through hole (e.g., Jh1 in this case) of the electrically conductive member J is supposed to be 2Rr, the through hole of the electrically conductive member J is formed to satisfy D<2Rr (i.e., so as to pass the end of the tubular thermoelectric generator T1 through itself). Also, if the diameter of the flat portion 56f of the electrically conductive ring member 56 is supposed to be 2Rf, the through hole of the electrically conductive member J is formed to satisfy 2Rr<2Rf so that the respective surfaces of the flat portion 56f and ring portion Jr1 contact with each other just as intended.

Optionally, the end of the tubular thermoelectric generator T may have a chamfered portion Cm as shown in FIG. 33. The reason is that when the end of the tubular thermoelectric generator T (e.g., tubular thermoelectric generator T1) is inserted into the through hole 56a of the electrically conductive ring member 56, the elastic portions 56r of the electrically conductive ring member 56 and the end of the tubular thermoelectric generator T contact with each other, thus possibly getting the end of the tubular thermoelectric generator T damaged. However, by providing such a chamfered portion Cm at the end of the tubular thermoelectric generator T, such damage that could be done on the end of the tubular thermoelectric generator T due to the contact between the elastic portions 56r and the end of the tubular thermoelectric generator T can be avoided. And by avoiding the occurrence of the damage on the end of the tubular thermoelectric generator T, the electrically conductive member J can be sealed more securely from the hot and cold media. In addition, electrical contact failure between the outer peripheral surface of the tubular thermoelectric generator T and the elastic portions 56r can also be reduced. The chamfered portion Cm may have the curved surface as shown in FIG. 33 or may also have a planar surface.

In this manner, the electrically conductive member J1 is electrically connected to the outer peripheral surface at the end of the tubular thermoelectric generator T via the electrically conductive ring member 56. According to this embodiment, by fastening the first and second plate portions 36a and 36b together, the flat portion 56f of the electrically conductive ring member 56 and the electrically conductive member J can make electrical contact with each other with good stability and sealing described above can be established.

Furthermore, by arranging the electrically conductive ring member 56 with respect to the end of the tubular thermoelectric generator T, the electrically conductive member J1 can be sealed more tightly. As described above, the first O-ring 52a is pressed against the seating surface Bsa via the electrically conductive member J1 and the electrically conductive ring member 56. In this case, the electrically conductive ring member 56 has the flat portion 56f. That is to say, the pressure is applied to the first O-ring 52a through the flat portion 56f of the electrically conductive ring member 56. Since the electrically conductive ring member 56 has the flat portion 56f, the pressure can be applied evenly to the first O-ring 52a. As a result, the first O-ring 52a can be pressed against the seating surface Bsa firmly enough to get sealing done just as intended from the fluid in the container. In the same way, proper pressure can also be applied to the second O-ring 52b, and therefore, sealing can be done from the fluid outside of the container, too.

Next, it will be described how the electrically conductive ring member 56 may be fitted into the tubular thermoelectric generator T.

First of all, as shown in FIG. 29A, the respective ends of the tubular thermoelectric generators T1 and T2 are inserted into the openings A61 and A62 of the first plate portion 36a. After that, the first O-rings 52a (and the washers 54 if necessary) are fitted into the tubular thermoelectric generators through their tip ends and pushed deeper into the openings A61 and A62. Next, the electrically conductive ring members 56 are fitted into the tubular thermoelectric generators through their tip ends and pushed deeper into the openings A61 and A62. Subsequently, the electrically conductive member J1 (and the washers 54 and second O-rings 52b if necessary) is/are fitted into the tubular thermoelectric generators through their tip ends and pushed deeper into the openings A61 and A62. Finally, the sealing surface of the second plate portion 36b is arranged to face the first plate portion 36a and the first and second plate portions 36a and 36b are fastened together by flange connection, for example, so that the respective tip ends of the tubular thermoelectric generators are inserted into the openings of the second plate portion 36b. In this case, the first and second plate portions 36a and 36b may be fastened together with bolts and nuts through the holes 36bh cut through the second plate portion 36b (shown in FIG. 7B) and the holes cut through the first plate portion 36a.

The electrically conductive ring member 56 is not connected permanently to, and is readily removable from, the tubular thermoelectric generator T. For example, when the tubular thermoelectric generator T is replaced with a new tubular thermoelectric generator T, to remove the electrically conductive ring member 56 from the tubular thermoelectric generator T, the operation of fitting the electrically conductive ring members 56 into the tubular thermoelectric generators T may be performed in reverse order. The electrically conductive ring member 56 may be used a number of times (i.e., is recyclable) or replaced with a new one.

The electrically conductive ring member 56 does not always have to have the exemplary shape shown in FIG. 30A. The ratio of the width of the flat portion 56f (as measured radially) to the radius of the through hole 56a may also be defined arbitrarily. The respective elastic portions 56r may have any of various shapes and the number of the elastic portions 56r to provide may be set arbitrarily, too.

FIG. 30B is a perspective view illustrating another exemplary shape of the electrically conductive ring member 56. The electrically conductive ring member 56 shown in FIG. 30B also has a ringlike flat portion 56f and a plurality of elastic portions 56r. The flat portion 56f has a through hole 56a. Each of the elastic portions 56r projects from around the through hole 56a of the flat portion 56f and is biased toward the center of the through hole 56a with elastic force. In this example, the number of the elastic portions 56r to provide is four. The number of the elastic portions 56r may be two but is suitably three or more. For example, six or more elastic portions 56r may be provided.

It should be noted that according to such an arrangement in which the flat-plate electrically conductive member J is brought into contact with the flat portion 56f of the electrically conductive ring member 56, some gap (or clearance) may be left between the through hole inside the ring portion of the electrically conductive member J and the tubular thermoelectric generator to be inserted into the hole. Thus, even if the tubular thermoelectric generator is made of a brittle material, the tubular thermoelectric generator can also be connected with good stability without allowing the ring portion Jr1 of the electrically conductive member J to do damage on the tubular thermoelectric generator.

<Electrical Connection Via Connection Plate>

As described above, the electrically conductive member (connection plate) is housed inside the channel C which has been cut to interconnect at least two of the openings A that have been cut through the plate 36. Note that the respective ends of the two tubular thermoelectric generators may be electrically connected together without the electrically conductive ring members 56. In other words, the electrically conductive ring members 56 may be omitted from the channel C. In that case, the respective ends of the two tubular thermoelectric generators may be electrically connected together via an electric cord, a conductor bar, or electrically conductive paste, for example. If the ends of the two tubular thermoelectric generators are electrically connected together via an electric cord, those ends of the tubular thermoelectric generators and the cord may be electrically connected together by soldering, crimping or crocodile-clipping, for example.

However, by electrically connecting the respective ends of the two tubular thermoelectric generators via the electrically conductive member J1 that is housed in the channel C as shown in FIGS. 28 and 29A, the respective ends of the tubular thermoelectric generators T and the electrically conductive member J1 can be electrically connected together more stably. If the electrically conductive member J has a flat plate shape (e.g., if the connecting portion Jc has a broad width), the electrical resistance between the two tubular thermoelectric generators can be reduced compared to a situation where an electric cord is used. In addition, since no terminals are fixed onto the ends of the tubular thermoelectric generators T, the tubular thermoelectric generators T can be replaced easily. With the electrically conductive ring members 56, the respective ends of the two tubular thermoelectric generators can be not only fixed to each other but also electrically connected together.

In the thermoelectric generator unit 100, the plate 34 or 36 has the channel C which has been cut to connect together at least two of the openings A, and therefore, electrical connecting function which has never been provided by any tube sheet for a heat exchanger is realized. In addition, since the thermoelectric generator unit 100 can be configured so that the first and second O-rings 52a and 52b press the seating surfaces Bsa and Bsb, respectively, sealing can be established so that either airtight or watertight condition is maintained with the ends of the tubular thermoelectric generators T inserted. As can be seen, by providing the channel C for the plate 34 or 36, even in an implementation in which the electrically conductive ring members 56 are omitted, the ends of the two tubular thermoelectric generators can also be electrically connected together and sealing from the fluids (e.g., the hot and cold media) can also be established.

<Relation Between Direction of Flow of Heat and Tilt Direction of Planes of Stacking>

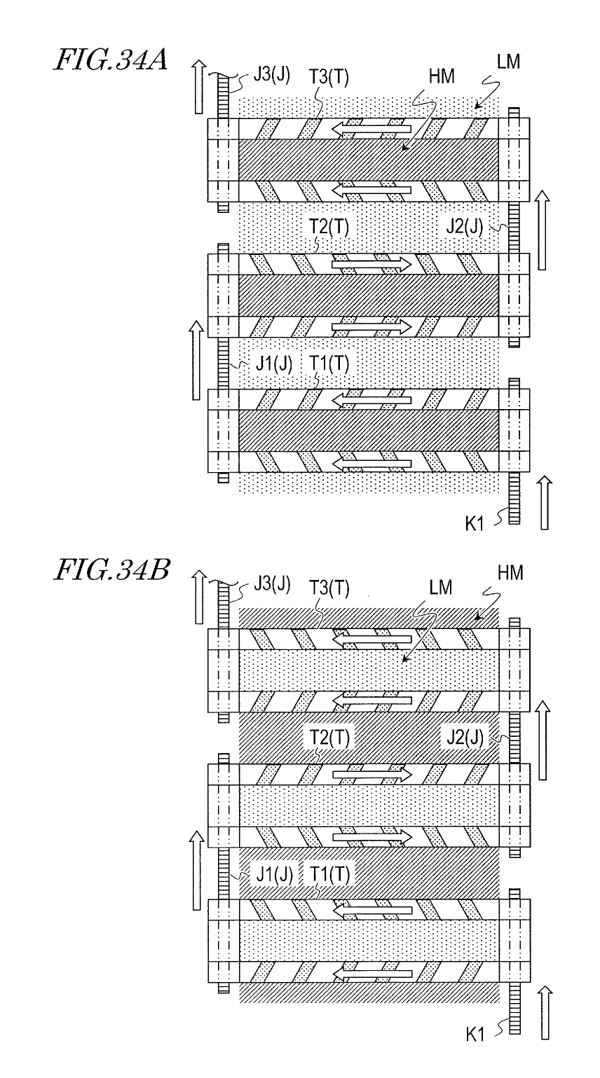

Now, the relation between the direction of flow of heat in each thermoelectric generation tube T and the tilt direction of the planes of stacking in the thermoelectric generation tube T will be described with reference to FIGS. 34A and 34B.

FIG. 34A schematically illustrates how electric current flows in tubular thermoelectric generators T which are electrically connected together in series. FIG. 34A schematically illustrates cross sections of three (T1 to T3) of the tubular thermoelectric generators T1 to T10.

In FIG. 34A, an electrically conductive member (terminal plate) K1 is connected to one end of the tubular thermoelectric generator T1 (e.g., at the first electrode end), while an electrically conductive member (connection plate) J1 is connected to the other end (e.g., at the second electrode end) of the tubular thermoelectric generator T1. The electrically conductive member J1 is also connected to one end (i.e., at the first electrode end) of the tubular thermoelectric generator T2. As a result, the tubular thermoelectric generators T1 and T2 are electrically connected together. Furthermore, the other end (i.e., at the second electrode end) of the tubular thermoelectric generator T2 and one end (i.e., at the first electrode end) of the tubular thermoelectric generator T3 are electrically connected together via the electrically conductive member J2.

In this case, as shown in FIG. 34A, the tilt direction of the planes of stacking in the tubular thermoelectric generator T2 is opposite from the tilt direction of the planes of stacking in the tubular thermoelectric generator T1. Likewise, the tilt direction of the planes of stacking in the tubular thermoelectric generator T3 is opposite from the tilt direction of the planes of stacking in the tubular thermoelectric generator T2. That is to say, in this thermoelectric generator unit 100, each of the tubular thermoelectric generator T1 to T10 has planes of stacking that is tilted in the opposite direction from those of an adjacent one of the tubular thermoelectric generators that is connected to itself via a connection plate.

Suppose the hot medium HM has been brought into contact the inner peripheral surface of each of the tubular thermoelectric generators T1 to T3, and the cold medium LM has been brought into contact with their outer peripheral surface, as shown in FIG. 34A. In that case, in the tubular thermoelectric generator T1, electric current flows from the right to the left on the paper, for example. On the other hand, in the tubular thermoelectric generator T2, of which the planes of stacking are tilted in the opposite direction from those of the tubular thermoelectric generator T1, electric current flows from the left to the right on the paper.

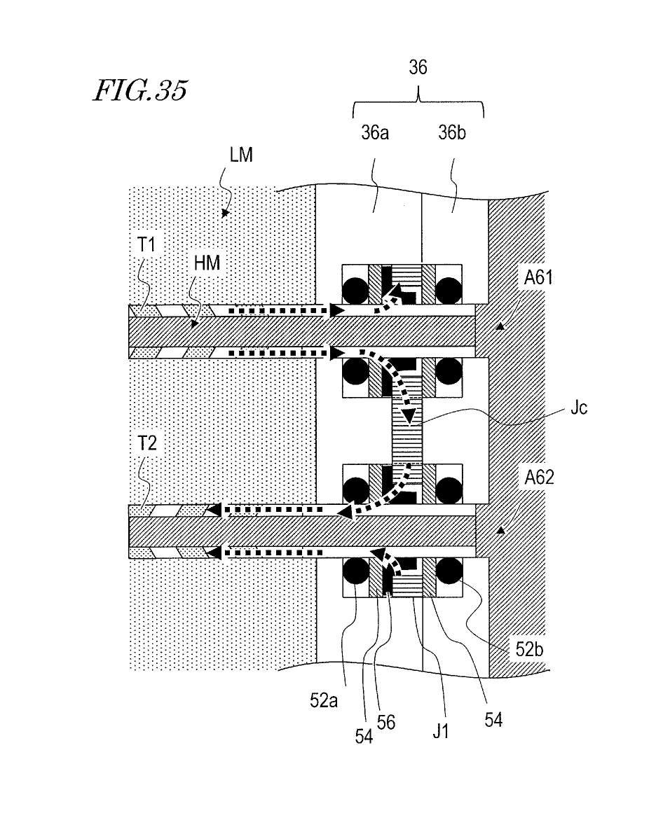

FIG. 35 schematically shows the directions in which electric current flows through the two openings A61 and A62 and their surrounding region. FIG. 35 is a drawing corresponding to portion (a) of FIG. 28. In FIG. 35, the flow directions of the electric current are schematically indicated by the dotted arrows. As shown in FIG. 35, the electric current generated in the tubular thermoelectric generator T1 flows toward the tubular thermoelectric generator T2 through the electrically conductive ring member 56 of the opening A61, the electrically conductive member J1 and the electrically conductive ring member 56 of the opening A62 in this order. The electric current that has flowed into the tubular thermoelectric generator T2 is combined with electric current generated in the tubular thermoelectric generator T2, and the electric current thus combined flows toward the tubular thermoelectric generator T3. As shown in FIG. 34A, the planes of stacking of the tubular thermoelectric generator T3 are tilted in the opposite direction from those of the tubular thermoelectric generator T2. That is why in the tubular thermoelectric generator T3, the electric current flows from the right to the left in FIG. 34A. Consequently, the electromotive forces generated in the respective tubular thermoelectric generators T1 to T3 get superposed one upon the other without canceling each other. By sequentially connecting a plurality of tubular thermoelectric generators T together in this manner so that the tilt direction of their planes of stacking inverts alternately one generator after another, an even greater voltage can be extracted from the thermoelectric generator unit.

Next, look at FIG. 34B, which also schematically shows, just like FIG. 34A, electric current flowing through tubular thermoelectric generators T which are electrically connected in series. As in the example shown in FIG. 34A, the tubular thermoelectric generators T1 to T3 are also sequentially connected in FIG. 34B so that the tilt direction of their planes of stacking inverts alternately one generator after another. In this case, since the planes of stacking in one of any two adjacent tubular thermoelectric generators connected together are tilted in the opposite direction from the planes of stacking in the other tubular thermoelectric generator, the electromotive forces generated in the respective tubular thermoelectric generators T1 to T3 get superposed one upon the other without canceling each other.

If the cold medium LM is brought into contact with the inner peripheral surface of each of the tubular thermoelectric generators T1 to T3 and the hot medium HM is brought into contact with their outer peripheral surface as shown in FIG. 34B, the polarity of voltage generated in each of the tubular thermoelectric generators T1 to T3 becomes opposite from the one shown in FIG. 34A. In other words, if the direction of the temperature gradient in each tubular thermoelectric generator is inverted, then the polarity of the electromotive force in that tubular thermoelectric generator (which may also be called the direction of electric current flowing through that tubular thermoelectric generator) inverts. Therefore, to make electric current flow from the electrically conductive member K1 toward the electrically conductive member J3 as in FIG. 34A, the configurations on the first and second electrode sides in each of the tubular thermoelectric generators T1 to T3 may be opposite from the configurations shown in FIG. 34A. It should be noted that electric current flowing directions shown in FIGS. 34A and 34B are just examples. Depending on the material to make the metal layers 20 and the thermoelectric material to make the thermoelectric material layers 22, the electric current flowing directions may be opposite from the ones shown in FIGS. 34A and 34B.

As already described with reference to FIGS. 34A and 34B, the polarity of the voltage generated in the tubular thermoelectric generator T depends on the tilt direction of the planes of stacking of that tubular thermoelectric generator T. That is why when the tubular thermoelectric generator T is going to be replaced, for example, the tubular thermoelectric generator T needs to be arranged appropriately with the temperature gradient between the inner and outer peripheral surfaces of the tubular thermoelectric generator T in the thermoelectric generator unit 100 taken into account.

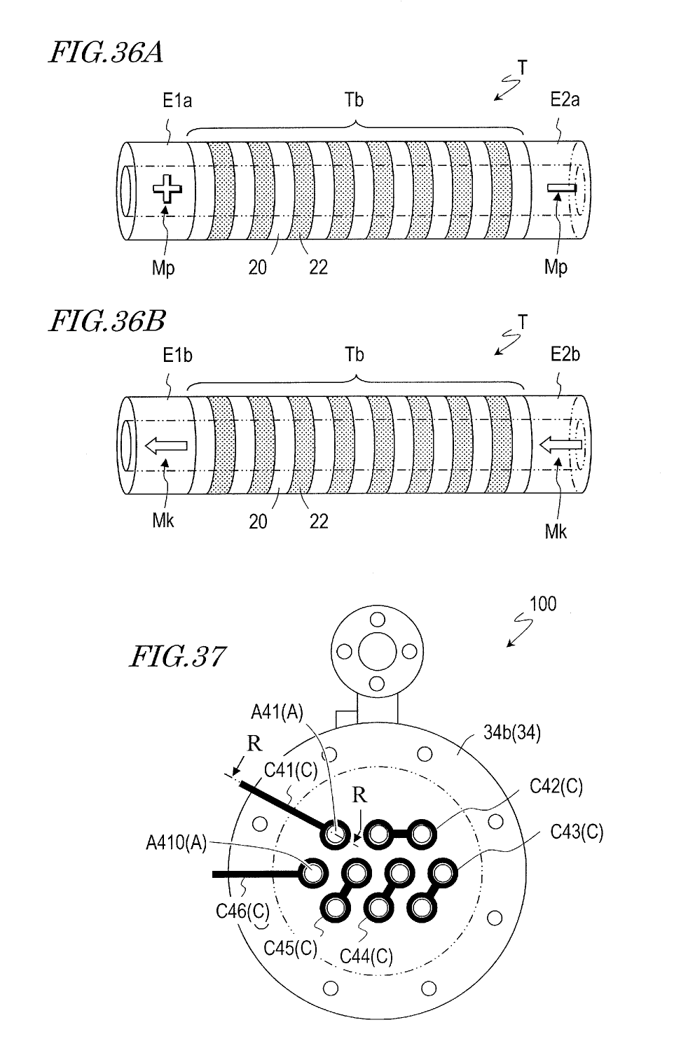

FIGS. 36A and 36B are perspective views each illustrating an exemplary tubular thermoelectric generator, of which the electrodes have indicators of their polarity. In the tubular thermoelectric generator T shown in FIG. 36A, molded portions (embossed marks) Mp indicating the polarity of the voltage generated in the tubular thermoelectric generator have been formed on the first and second electrodes E1a and E2a. On the other hand, in the tubular thermoelectric generator T shown in FIG. 36B, marks Mk indicating whether the planes of stacking in the tubular thermoelectric generator T are tilted toward the first electrode E1b or the second electrode E2b are left on the first and second electrodes E1b and E2b. These molded portions (e.g., convex or concave portions) and marks may be combined together. Optionally, these molded portions and marks may be added to the tube body Tb or to only one of the first and second electrodes.

In this manner, molded portions or marks indicating the polarity of the voltage generated in the tubular thermoelectric generator T may be added to the first and second electrodes, for example. In that case, it can be seen quickly just from the appearance of the tubular thermoelectric generator T whether the planes of stacking of the tubular thermoelectric generator T are tilted toward the first electrode or the second electrode. Optionally, instead of adding such molded portions or marks, the first and second electrodes may have mutually different shapes. For example, the lengths, thicknesses or cross-sectional shapes as viewed on a plane that intersects with the axial direction at right angles may be different from each other between the first and second electrodes.

<Electrical Connection Structure for Extracting Electric Power Out of Thermoelectric Generator Unit 100>

Now look at FIG. 5 again. In the example illustrated in FIG. 5, ten tubular thermoelectric generators T1 to T10 are electrically connected in series via electrically conductive members J1 to J9. Each of these electrically conductive members J1 to J9 connects its associated two tubular thermoelectric generators T together just as described above. An exemplary electrical connection structure for extracting electric power out of the thermoelectric generator unit 100 from the two tubular generators T1 and T10 located at both ends of the series circuit will now be described.

First, look at FIG. 37, which illustrates the other side face of the thermoelectric generator unit 100 shown in FIG. 7A (left side view). While FIG. 7B shows a configuration for the plate 36, FIG. 37 shows a configuration for the plate 34. Any member or operation that has already been described with respect to the plate 36 will not be described all over again to avoid redundancies.

As shown in FIG. 37, each of the channels C42 to C45 interconnects at least two of the openings A cut through the plate 34. In the present specification, such channels will be sometimes hereinafter referred to as “interconnections”. The electrically conductive members housed in these interconnections may have the same configuration as the electrically conductive member J1. On the other hand, the channel C41 is provided for the plate 34 so as to run from the opening A41 to the outer edge of the plate 34. In the present specification, such a channel provided to run from an opening of a plate to its outer edge will be sometimes hereinafter referred to as a “terminal connection”. The channels C41 and C46 shown in FIG. 37 are terminal connections. In each terminal connection, the electrically conductive member functioning as a terminal for connecting to an external circuit is housed.

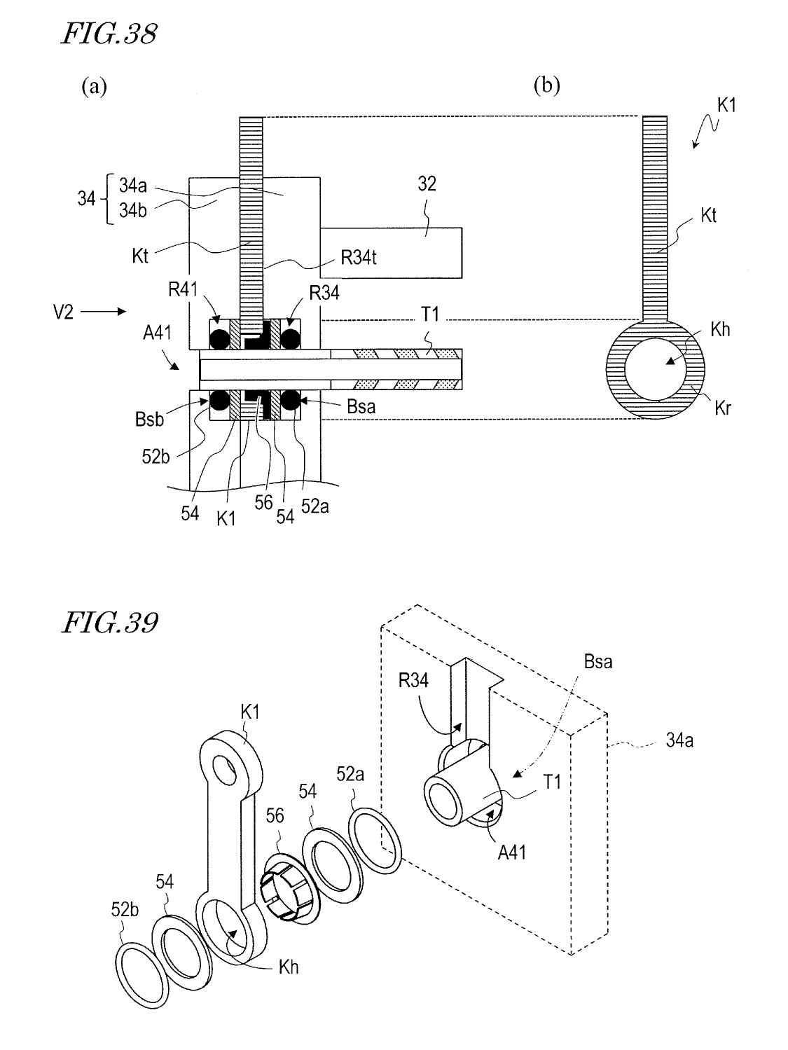

Portion (a) of FIG. 38 is a schematic partial cross-sectional view of the plate 34. Specifically, portion (a) of FIG. 38 schematically illustrates a cross section of the plate as viewed on a plane including the center axis of the tubular thermoelectric generator T1 and corresponding to the plane R-R′ shown in FIG. 37. More specifically, portion (a) of FIG. 38 illustrates the structure of one A41 of multiple openings A that the plate 34 has and a region surrounding it. Portion (b) of FIG. 38 illustrates the appearance of an electrically conductive member K1 as viewed in the direction indicated by the arrow V2 in portion (a) of FIG. 38. This electrically conductive member K1 has a through hole Kh at one end. More specifically, this electrically conductive member K1 includes a ring portion Kr with the through hole Kh and a terminal portion Kt extending outward from the ring portion Kr. Just like the electrically conductive member J1, this electrically conductive member K1 is also typically made of a metal.

As shown in portion (a) of FIG. 38, one end of the tubular thermoelectric generator T1 (on the first electrode side) is inserted into the opening A41 of the plate 34. In this state, the end of the tubular thermoelectric generator T1 is inserted into the through hole Kh of the electrically conductive member K1. As can be seen, an electrically conductive member J or K1 according to this embodiment can be said to be an electrically conductive plate with at least one hole to pass the tubular thermoelectric generator T through. The structure of the opening A410 and the region surrounding it is the same as that of the opening A41 and the region surrounding it except that the end of the tubular thermoelectric generator T10 is inserted into the opening A410 of the plate 34.

In the example illustrated in portion (a) of FIG. 38, the first plate portion 34a has a recess R34 which has been cut for the opening A41. This recess R34 includes a groove portion R34t which extends from the opening A41 through the outer edge of the first plate portion 34a. In this groove portion R34t, located is the terminal portion Kt of the electrically conductive member K1. In this example, the space defined by the recess R34 and a recess R41 which has been cut in the second plate portion 34b forms a channel to house the electrically conductive member K1. As in the example illustrated in portion (a) of FIG. 28, not only the electrically conductive member K1 but also a first O-ring 52a, washers 54, an electrically conductive ring member 56 and a second O-ring 52b are housed in the channel C41 in the example illustrated in portion (a) of FIG. 38, too. And the end of the tubular thermoelectric generator T1 goes through the holes of these members. The first O-ring 52a establishes sealing so as to prevent a fluid that has been supplied into the shell 32 from entering the channel C41. On the other hand, the second O-ring 52b establishes sealing so as to prevent a fluid located outside of the second plate portion 34b from entering the channel C41.

FIG. 39 is an exploded perspective view schematically illustrating the channel C41 to house the electrically conductive member K1 and its vicinity. For example, a first O-ring 52a, a washer 54, an electrically conductive ring member 56, the electrically conductive member K1, another washer 54 and a second O-ring 52b may be inserted into the opening A41 from outside of the container 30. The sealing surface of the second plate portion 34b (i.e., the surface that faces the first plate portion 34a) has substantially the same configuration as the sealing surface of the second plate portion 36b shown in FIG. 29B. Thus, by fastening the first and second plate portions 34a and 34b together, the second seating surface Bsb of the second plate portion 34b presses the first O-ring 52a against the seating surface Bsa of the first plate portion 34a through the second O-ring 52b, electrically conductive member K1 and electrically conductive ring member 56. In this manner, the electrically conductive member K1 can be sealed from the hot and cold media.

The ring portion Kr of the electrically conductive member K1 contacts with the flat portion 56f of the electrically conductive ring member 56 inside the opening A cut through the plate 34. In this manner, the electrically conductive member K1 is electrically connected to the outer peripheral surface at the end of the tubular thermoelectric generator T via the electrically conductive ring member 56. In this case, one end of the electrically conductive member K1 (i.e., the terminal portion Kt) sticks out of the plate 34 as shown in portion (a) of FIG. 38. Thus, that part of the terminal portion Kt that sticks out of the plate 34 may function as a terminal to connect the thermoelectric generator unit to an external circuit. As shown in FIG. 39, that part of the terminal portion Kt to stick out of the plate 34 may have a ring shape. In the present specification, an electrically conductive member, one end of which receives a tubular thermoelectric generator inserted and the other end of which sticks out, will be sometimes hereinafter referred to as a “terminal plate”.

As described above, in this thermoelectric generator unit 100, the tubular thermoelectric generators T1 and T10 are respectively connected to the two terminal plates housed in the terminal connections. In addition, between those two terminal plates, those tubular thermoelectric generators T1 through T10 are electrically connected together in series via the connection plate housed in the interconnection of the channel. Consequently, through the two terminal plates, one end of which sticks out of the plate (34, 36), the electric power generated by those tubular thermoelectric generators T1 to T10 can be extracted out of this thermoelectric generator unit 100.

The arrangements of the electrically conductive ring member 56 and electrically conductive member J, K1 may be changed appropriately inside the channel C. In that case, the electrically conductive ring member 56 and the electrically conductive member (J, K1) just need to be arranged so that the elastic portions 56r of the electrically conductive ring member 56 are inserted into the through hole Jh1, Jh2 or Kh of the electrically conductive member. Also, as mentioned above, in an implementation in which the electrically conductive ring member 56 is omitted, the end of the tubular thermoelectric generator T may be electrically connected to the electrically conductive member K1. Optionally, part of the flat portion 56f of the electrically conductive ring member 56 may be extended and used in place of the terminal portion Kt of the electrically conductive member K1. In that case, the electrically conductive member K1 may be omitted.

In the embodiments described above, a channel C is formed by respective recesses cut in the first and second plate portions. However, the channel C may also be formed by a recess which has been cut in one of the first and second plate portions. If the container 30 is made of a metallic material, the inside of the channel C may be coated with an insulator to prevent the electrically conductive members (i.e., the connection plates and the terminal plates) from becoming electrically conductive with the container 30. For example, the plate 34 (consisting of the plate portions 34a and 34b) may be comprised of a body made of a metallic material and an insulating coating which covers the surface of the body at least partially. Likewise, the plate 36 (consisting of the plate portions 36a and 36b) may also be comprised of a body made of a metallic material and an insulating coating which covers the surface of the body at least partially. If the respective surfaces of the recesses cut in the first and second plate portions are coated with an insulator, the insulating coating can be omitted from the surface of the electrically conductive member.

<Another Exemplary Structure to Establish Sealing and Electrical Connection>

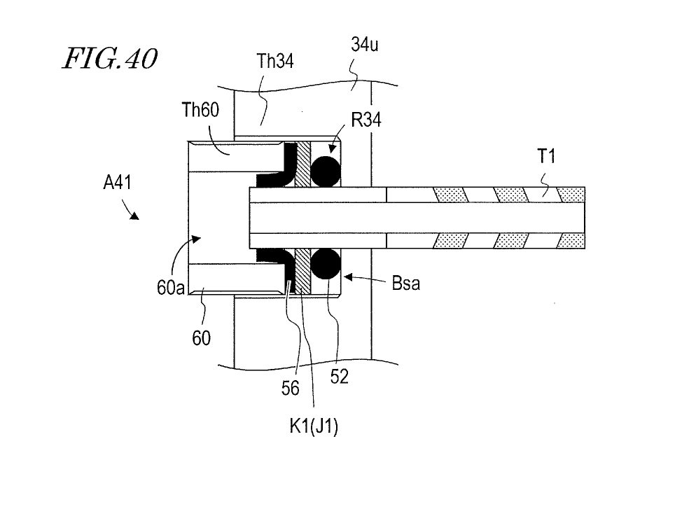

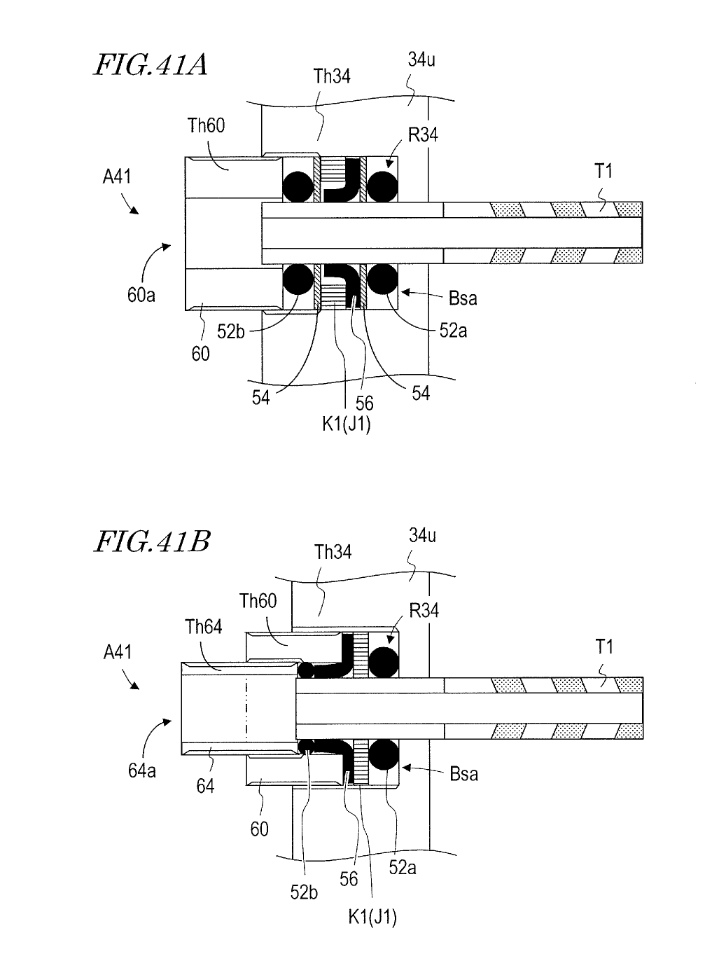

FIG. 40 is a cross-sectional view illustrating an exemplary structure for separating the medium in contact with the outer peripheral surface of each of the tubular thermoelectric generators T1 to T10 from the medium in contact with the inner peripheral surface of the tubular thermoelectric generator T so as to prevent those media from mixing together. In the example illustrated in FIG. 40, a bushing 60 is inserted from outside of the container 30, thereby separating the hot and cold media from each other and electrically connecting the tubular thermoelectric generator and the electrically conductive member together.

In the example illustrated in FIG. 40, the opening A41 cut through the plate 34u has an internal thread portion Th34. More specifically, the wall surface of the recess R34 that has been cut with respect to the opening A41 of the plate 34u has the thread. The busing 60 with an external thread portion Th60 is inserted into the recess R34. The bushing 60 has a through hole 60a that runs in the axial direction. In this case, the end of the tubular thermoelectric generator T1 has been inserted into the opening A41 of the plate 34u. That is why when the busing 60 is inserted into the recess R34, the through hole 60a communicates with the internal flow path of the tubular thermoelectric generator T1.

Inside the space left between the recess R34 and the busing 60, arranged are various members to establish sealing and electrical connection. In the example illustrated in FIG. 40, an O-ring 52, the electrically conductive member K1 and the electrically conductive ring member 56 are arranged in this order from the seating surface Bsa of the plate 34u toward the outside of the container 30. The end of the tubular thermoelectric generator T1 is inserted into the respective holes of these members. The O-ring 52 contacts with the seating surface Bsa of the plate 34u and the outer peripheral surface at the end of the tubular thermoelectric generator T1. In this case, when the external thread portion Th60 is inserted into the internal thread portion Th34, the external thread portion Th60 presses the O-ring 52 against the seating surface Bsa via the flat portion 56f of the electrically conductive ring member 56 and the electrically conductive member K1. As a result, sealing can be established so as to prevent the fluid supplied into the shell 32 and the fluid supplied into the internal flow path of the tubular thermoelectric generator T1 from mixing with each other. In addition, since the outer peripheral surface of the tubular thermoelectric generator T1 contacts with the elastic portions 56r of the electrically conductive ring member 56 and since the flat portion 56f of the electrically conductive ring member 56 contacts with the ring portion Kr of the electrically conductive member K1, the tubular thermoelectric generator and the electrically conductive member can be electrically connected together.

As can be seen, by using the members shown in FIG. 40, the hot and cold media can be separated from each other and the tubular thermoelectric generator and the electrically conductive member can be electrically connected together with a simpler configuration.

FIGS. 41A and 41B are cross-sectional views illustrating two other exemplary structures for separating the hot and cold media from each other and electrically connecting the tubular thermoelectric generator and the electrically conductive member together. Specifically, in the example shown in FIG. 41A, a first O-ring 52a, a washer 54, the electrically conductive ring member 56, the electrically conductive member K1, another washer 54 and a second O-ring 52b are arranged in this order from the seating surface Bsa of the plate 34u toward the outside of the container 30. In the example illustrated in FIG. 41A, the external thread portion Th60 presses the O-ring 52a against the seating surface Bsa via the electrically conductive member K1 and the flat portion 56f of the electrically conductive ring member 56. On the other hand, in the example shown in FIG. 41B, a first O-ring 52a, the electrically conductive member K1, the electrically conductive ring member 56 and a second O-ring 52b are arranged in this order from the seating surface Bsa of the plate 34u toward the outside of the container 30. In addition, in FIG. 41B, another busing 64 with a through hole 64a has been inserted into the through hole 60a of the busing 60. The through hole 64a also communicates with the internal flow path of the tubular thermoelectric generator T1. In the example illustrated in FIG. 41B, the external thread portion Th64 of the busing 64 presses the second O-ring 52b against the seating surface Bsa. Sealing from both of the fluids (the hot and cold media) can be established by arranging the first and second O-rings 52a and 52b in this manner. By establishing sealing from both of the fluids (the hot and cold media), corrosion of the electrically conductive ring member 56 can be minimized.

As described above, one end of the terminal portion Kt of the electrically conductive member K1 sticks out of the plate 34u and can function as a terminal to connect the thermoelectric generator unit to an external circuit. In the implementations shown in FIGS. 40, 41A and 41B, the electrically conductive member K1 (terminal plate) may be replaced with a connection plate such as the electrically conductive member J1. In that case, the end of the tubular thermoelectric generator T1 is inserted into the through hole Jh1. If necessary, a washer 54 may be arranged between the O-ring and the electrically conductive member, for example.

<Exemplary Configuration for Thermoelectric Generator System>

Next, an exemplary configuration for a thermoelectric generator system according to the present disclosure will be described.

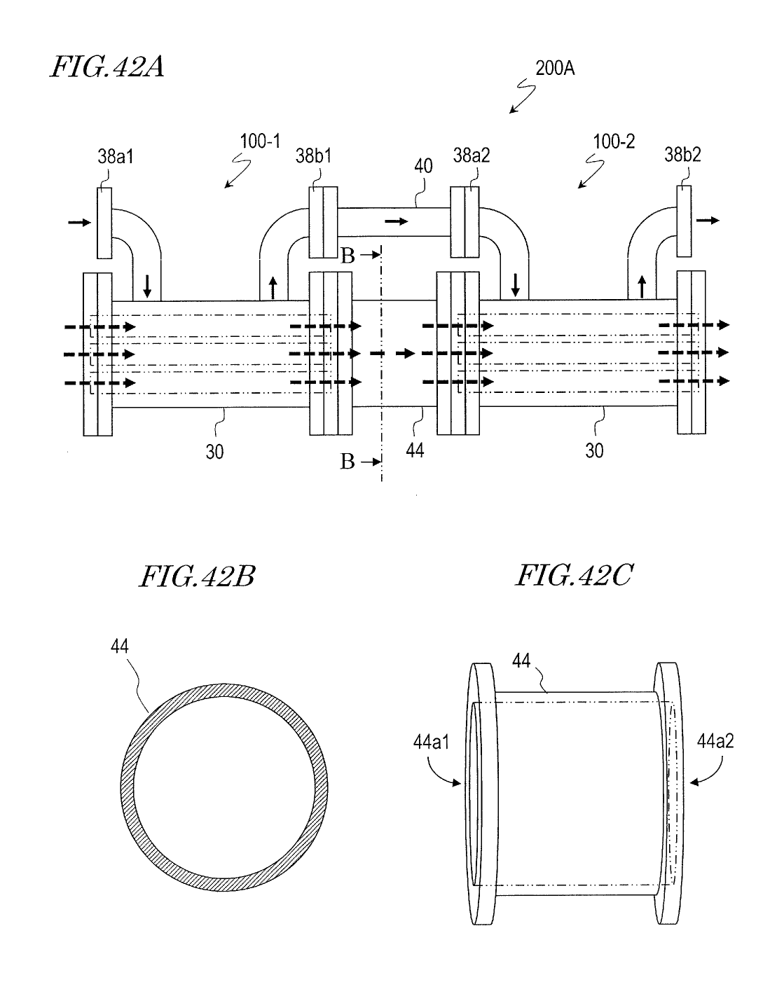

FIG. 42A illustrates an exemplary configuration for a thermoelectric generator system according to the present disclosure. FIG. 42B is a schematic cross-sectional view of the system as viewed on the plane B-B shown in FIG. 42A. And FIG. 42C is a perspective view illustrating an exemplary configuration for a buffer vessel that the thermoelectric generator system shown in FIG. 42A has. In FIG. 42A, the bold solid arrows generally indicate the flow direction of the medium in contact with the outer peripheral surface of a tubular thermoelectric generator (i.e., the medium flowing inside of the container 30 (and outside of the tubular thermoelectric generator)). On the other hand, the bold dashed arrows generally indicate the flow direction of the medium in contact with the inner peripheral surface of a tubular thermoelectric generator (i.e., the medium flowing through the through hole (i.e., the inner flow path) of the tubular thermoelectric generator). In the present specification, a conduit communicating with the fluid inlet and outlet ports of each container 30 will be sometimes hereinafter referred to as a “first medium path” and a conduit communicating with the flow path of each tubular thermoelectric generator will be sometimes hereinafter referred to as a “second medium path”. Also, in the following description, illustration of the flow rate control system 500 and input interface 528 will be sometimes omitted.

The thermoelectric generator system 200A shown in FIG. 42A includes first and second thermoelectric generator units 100-1 and 100-2, each of which has the same configuration as the thermoelectric generator unit 100 described above. This thermoelectric generator system 200A further includes a thick circular cylindrical buffer vessel 44 which is arranged between the first and second thermoelectric generator units 100-1 and 100-2. This buffer vessel 44 has a first opening 44a1 communicating with the respective flow paths of multiple tubular thermoelectric generators in the first thermoelectric generator unit 100-1 and a second opening 44a2 communicating with the respective flow paths of multiple tubular thermoelectric generators in the second thermoelectric generator unit 100-2.

In this thermoelectric generator system 200A, the medium that has been introduced through the fluid inlet port 38a1 of the first thermoelectric generator unit 100-1 sequentially flows through the container 30 of the first thermoelectric generator unit 100-1, the fluid outlet port 38b1 of the first thermoelectric generator unit 100-1, a relay conduit 40, the fluid inlet port 38a2 of the second thermoelectric generator unit 100-2 and the container 30 of the second thermoelectric generator unit 100-2 in this order to reach a fluid outlet port 38b2 (which is the first medium path). That is to say, the medium that has been supplied into the container 30 of the first thermoelectric generator unit 100-1 is supplied to the inside of the container 30 of the second thermoelectric generator unit 100-2 through the conduit 40. It should be noted that this conduit 40 does not have to be a straight one but may be a bent one, too.

On the other hand, the respective internal flow paths of the multiple tubular thermoelectric generators in the first thermoelectric generator unit 100-1 communicate with the respective internal flow paths of the multiple tubular thermoelectric generators in the second thermoelectric generator unit 100-2 through the first and second openings 44a1 and 44a2 of the buffer vessel 44 (which is the second medium path). The medium that has been introduced into the respective internal flow paths of the multiple tubular thermoelectric generators in the first thermoelectric generator unit 100-1 is confluent with each other in the buffer vessel 44 and then introduced into the respective internal flow paths of the multiple tubular thermoelectric generators in the second thermoelectric generator unit 100-2.

In a thermoelectric generator system including plurality of thermoelectric generator units, the second medium path communicating with the flow paths of the respective tubular thermoelectric generators may be designed arbitrarily. It should be noted that the degree of heat exchange to be carried out in a single container 30 via multiple tubular thermoelectric generators may vary from generator to generator because of their different positions. That is why if the internal flow path of each tubular thermoelectric generator in one of two adjacent thermoelectric generator units and the internal flow path of its associated tubular thermoelectric generator in the other thermoelectric generator unit are simply connected in series together, the temperature of the medium flowing through the internal flow paths will disperse more and more. And when such dispersion in the temperature of the medium flowing through the internal flow paths of the respective tubular thermoelectric generators grows, the power output levels of the respective tubular thermoelectric generators may also vary from one generator to another.

In this thermoelectric generator system 200A, the medium that has flowed through the respective internal flow paths of the multiple tubular thermoelectric generators in the first thermoelectric generator unit 100-1 into the buffer vessel 44 exchanges heat in the buffer vessel 44 and then is supplied to the internal flow paths of the multiple tubular thermoelectric generators in the second thermoelectric generator unit 100-2. Since the medium that has flowed through the internal flow paths of the multiple tubular thermoelectric generators in the first thermoelectric generator unit 100-1 into the buffer vessel 44 exchanges heat in the buffer vessel 44, the temperature of the medium can be more uniform. By mixing the medium flowing through the internal flow path of one tubular thermoelectric generator in this manner with the medium flowing through the internal flow path of another tubular thermoelectric generator, the temperature of the media flowing through the respective internal flow paths of multiple tubular thermoelectric generators can be made more uniform, which is advantageous.

In the example illustrated in FIG. 42A, the second medium path is designed so that the fluid flows in the same direction through the respective flow paths of multiple tubular thermoelectric generators T. However, the flow direction of the fluid through the flow paths of multiple tubular thermoelectric generators T does not have to be the same direction. Alternatively, the flow direction of the fluid through the flow paths of multiple tubular thermoelectric generators T may also be set in various manners according to the design of the flow paths of the hot and cold media. Also, in the thermoelectric generator system of the present disclosure, multiple thermoelectric generator units may be connected either in series to each other or parallel with each other.

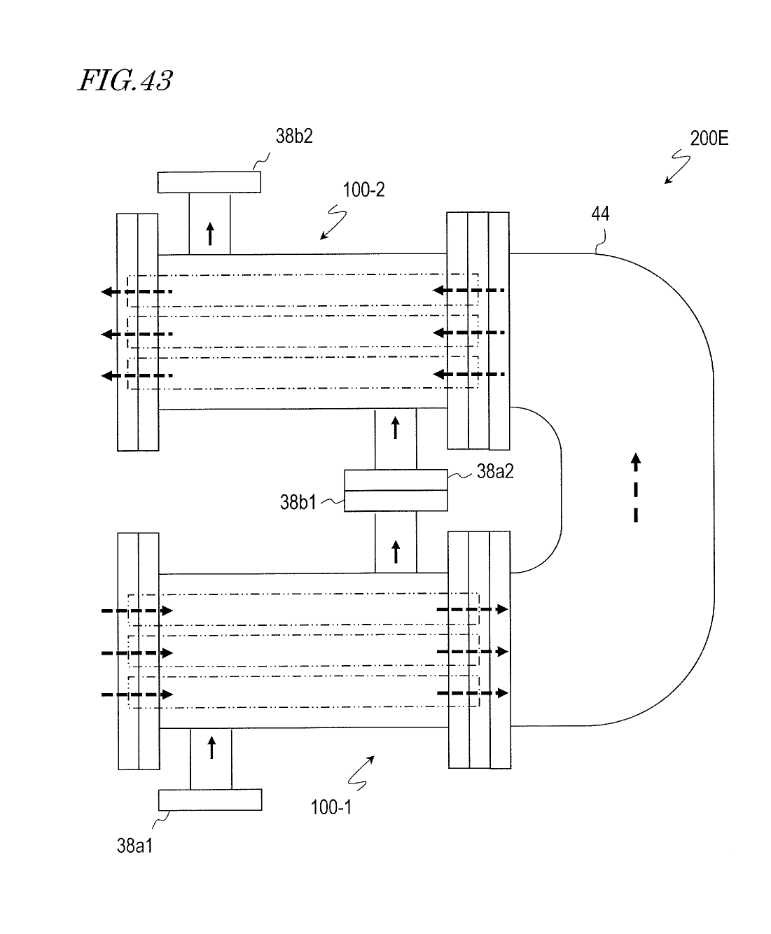

Next, look at FIG. 43, which illustrates still another exemplary configuration for a thermoelectric generator system according to the present disclosure. In FIG. 43, the bold solid arrows generally indicate the flow direction of the medium in contact with the outer peripheral surface of a tubular thermoelectric generator. On the other hand, the bold dashed arrows generally indicate the flow direction of the medium in contact with the inner peripheral surface of the tubular thermoelectric generator as in FIG. 42A. This thermoelectric generator system 200E is configured so that the flow direction of the fluid flowing through the respective flow paths of the multiple tubular thermoelectric generators T in the first thermoelectric generator unit 100-1 is antiparallel to that of the fluid flowing through the respective flow paths of the multiple tubular thermoelectric generators T in the second thermoelectric generator unit 100-2.

In this thermoelectric generator system 200E, the first and second thermoelectric generator units 100-1 and 100-2 are arranged spatially parallel with each other. For example, the second thermoelectric generator unit 100-2 may be arranged by the first thermoelectric generator unit 100-1. Optionally, the first and second thermoelectric generator units 100-1 and 100-2 may be vertically stacked one upon the other. In that case, the medium will flow vertically through the first medium path.

As shown in FIG. 43, the buffer vessel 44 may have a bent shape. As can be seen, in a thermoelectric generator system according to the present disclosure, the flow paths for hot and cold media may be designed in various manners. For example, the flow paths may be designed flexibly according to the area of the place where the thermoelectric generator system needs to be installed. The arrangements shown in FIGS. 42 and 43 are just examples. Rather the first medium path communicating with the fluid inlet and outlet ports of each container and the second medium path communicating with the respective flow paths of the tubular thermoelectric generators may be designed arbitrarily. Also, those thermoelectric generator units may be electrically connected either in series to each other or parallel with each other.

<Exemplary Configuration for Thermoelectric Generator System's Electric Circuit>

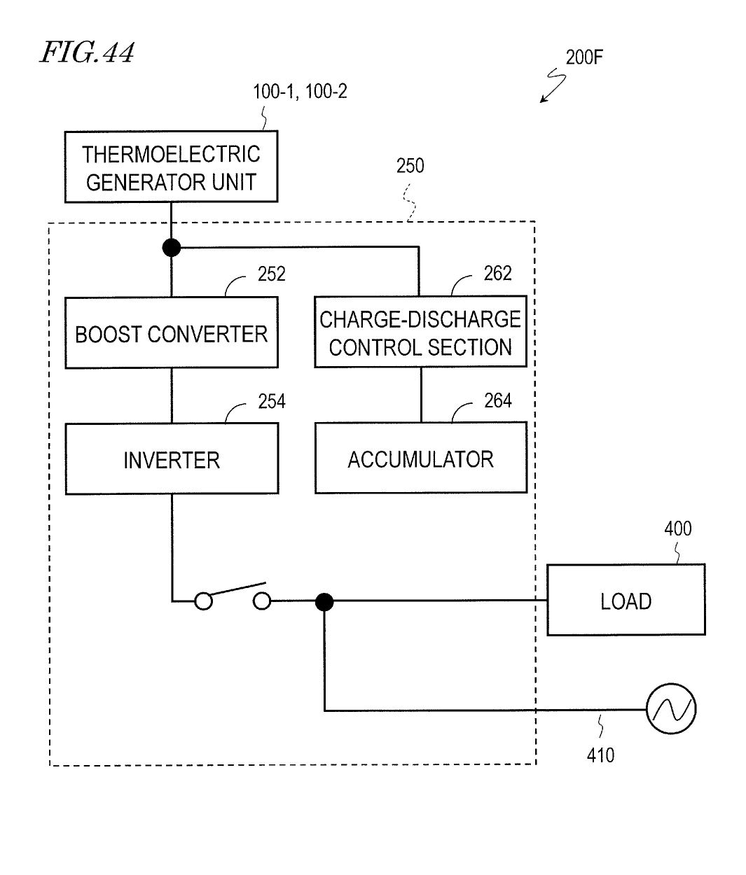

Next, an exemplary configuration for an electric circuit that the thermoelectric generator system according to the present disclosure may include will be described with reference to FIG. 44.

In the example shown in FIG. 44, the thermoelectric generator system 200F according to this embodiment includes an electric circuit 250 which receives electric power from the thermoelectric generator units 100-1, 100-2. That is to say, in one implementation, the plurality of electrically conductive members may have an electric circuit which is electrically connected to the plurality of tubular thermoelectric generators. Although the thermoelectric generator system 200F of this example includes only two thermoelectric generator units 100-1, 100-2, actually any other number of thermoelectric generator units may be provided as well.

The electric circuit 250 includes a boost converter 252 which boosts the voltage of the electric power supplied from the thermoelectric generator units 100-1, 100-2, and an inverter (DC-AC inverter) 254 which converts the DC power supplied from the boost converter 252 into AC power (of which the frequency may be 50/60 Hz, for example, but may also be any other frequency). The AC power may be supplied from the inverter 254 to a load 400. The load 400 may be any of various electrical or electronic devices that operate using AC power. The load 400 may have a charging function in itself, and does not have to be fixed to the electric circuit 250. Any AC power that has not been dissipated by the load 400 may be connected to a commercial grid 410 so that the electricity can be sold.

The electric circuit 250 in the example shown in FIG. 44 includes a charge-discharge control section 262 and an accumulator 264 for storing the DC power obtained from the thermoelectric generator units 100-1, 100-2. The accumulator 264 may be a chemical battery such as a lithium ion secondary battery, or a capacitor such as an electric double-layer capacitor, for example. The electric power stored in the accumulator 264 may be fed as needed to the boost converter 252 by the charge-discharge control section 262, and may be used or sold as AC power via the inverter 254.

Even if the thermoelectric generator system 200F according to this embodiment of the present disclosure includes the flow rate control system 500, the magnitude of the electric power supplied from the thermoelectric generator unit 100-1, 100-2 may still vary with time either periodically or irregularly. For example, if the rate at which the heat transfer medium is supplied from the heat transfer medium supply source to the tank 540 continues to decrease for a longer period of time than originally expected, the flow rate of the heat transfer medium supplied to the thermoelectric generator unit 100-1, 100-2 may not be maintained within a predetermined range with only the heat transfer medium stored in the tank 540. In that case, the power generation state of the thermoelectric generator unit 100-1, 100-2 will vary so significantly that the voltage of the electric power supplied from the thermoelectric generator unit 100-1, 100-2 and/or the amount of electric current will vary, too. However, even if the power generation state varies in this manner, the thermoelectric generator system 200F shown in FIG. 44 can also minimize the influence caused by such a variation in power output level by making the charge-discharge control section 262 accumulate electric power in the accumulator 264.

If the electric power generated is dissipated in real time, then the voltage step-up ratio of the boost converter 252 may be adjusted according to the variation in power generation state.

Optionally, the temperature of the hot medium may be controlled by adjusting the quantity of heat supplied from a high-temperature heat source (not shown) to the hot medium. In the same way, the temperature of the cold medium may also be controlled by adjusting the quantity of heat dissipated from the cold medium into a low-temperature heat source (not shown, either).

<Another Embodiment of Thermoelectric Generator System>

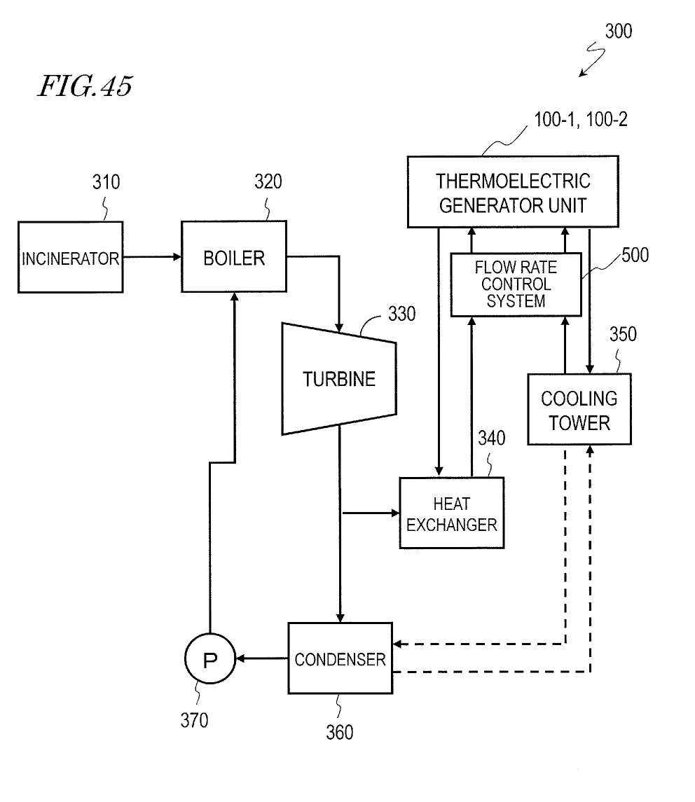

Another embodiment of a thermoelectric generator system according to the present disclosure will now be described with reference to FIG. 45.

In this embodiment, a plurality of thermoelectric generator units (such as 100-1 and 100-2) are provided for a general waste disposal facility (that is a so-called “garbage disposal facility” or a “clean center”). In recent years, at a waste disposal facility, high-temperature, high-pressure steam (at a temperature of 400 to 500 degrees Celsius and at a pressure of several MPa) is sometimes generated from the thermal energy produced when garbage (waste) is incinerated. Such steam energy is converted into electricity by turbine generator and the electricity thus generated is used to operate the equipment in the facility.

The thermoelectric generator system 300 of this embodiment includes a plurality of thermoelectric generator units. In the example illustrated in FIG. 45, the hot medium supplied to the thermoelectric generator units 100-1 and 100-2 has been produced based on the heat of combustion generated at the waste disposal facility. More specifically, this system includes an incinerator 310, a boiler 320 to produce high-temperature, high-pressure steam based on the heat of combustion generated by the incinerator 310, and a turbine 330 which is driven by the high-temperature, high-pressure steam produced by the boiler 320. The energy generated by the turbine 330 driven is given to a synchronous generator (not shown), which converts the energy into AC power (such as three-phase AC power).

The steam that has been used to drive the turbine 330 is turned back by a condenser 360 into liquid water, which is then supplied by a pump 370 to the boiler 320. This water is a working medium that circulates through a “heat cycle” formed by the boiler 320, turbine 330 and condenser 360. Part of the heat given by the boiler 320 to the water does work to drive the turbine 330 and then is given by the condenser 360 to cooling water. In general, cooling water circulates between the condenser 360 and a cooling tower 350.

As can be seen, only a part of the heat generated by the incinerator 310 is converted by the turbine 330 into electricity, and the thermal energy that the low-temperature, low-pressure steam has after the turbine 330 has been driven has not been converted into, and used as, electrical energy but often just dumped into the ambient according to conventional technologies. According to this embodiment, however, the low-temperature steam or hot water that has done work to drive the turbine 330 can be used effectively as a heat source for the hot medium. In this embodiment, heat is obtained by the heat exchanger 340 from the steam at such a low temperature (of 140 degrees Celsius, for example) and hot water at 99 degrees Celsius is obtained, for example. And this hot water is supplied as hot medium to the thermoelectric generator units 100-1, 100-2.

On the other hand, a part of the cooling water used at a waste disposal facility, for example, may be used as the cold medium. If the waste disposal facility has the cooling tower 350, water at about 10 degrees Celsius can be obtained from the cooling tower 350 and used as the cold medium. Alternatively, the cold medium does not have to be obtained from a special cooling tower but may also be well water or river water inside the facility or in the neighborhood.

The thermoelectric generator system 300 of this embodiment includes a flow rate control system 500 which controls the flow rate(s) of at least one of the hot water and cooling water flowing through the thermoelectric generator units 100-1 and 100-2 by reference to “information” about the operation condition of the thermoelectric generator system 300 or a preset target power output level. This flow rate control system 500 can adjust the flow rate of the hot water flowing into the thermoelectric generator units 100-1, 100-2 so that even if the flow rate of the hot Water supplied from the heat exchanger 340 has decreased, a decrease in the power output level of the thermoelectric generator units 100-1, 100-2 is minimized.

The thermoelectric generator units 100-1, 100-2 shown in FIG. 45 may be connected to the electric circuit 250 shown in FIG. 44, for example. The electricity generated by the thermoelectric generator units 100-1, 100-2 may be either used in the facility or accumulated in the accumulator 264. The extra electric power may be converted into AC power and then sold through the commercial grid 410.

The thermoelectric generator system 300 shown in FIG. 45 has a configuration in which a plurality of thermoelectric generator units are incorporated into the waste heat utilization system of a waste disposal facility including the boiler 320 and the turbine 330. However, to operate the thermoelectric generator units 100-1, 100-2, the boiler 320, turbine 330, condenser 360 and heat exchanger 340 are not indispensable members. If there is any gas or hot water at a relatively low temperature which has been just disposed of according to conventional technologies, that gas or water may be effectively used as hot medium directly. Or another gas or liquid may be heated by a heat exchanger and used as a hot medium. The system shown in FIG. 45 is just one of many practical examples.

As is clear from the foregoing description of embodiments, an embodiment of a thermoelectric generator system according to the present disclosure can collect and utilize effectively such thermal energy that has been just dumped unused into ambient according to conventional technologies. For example, by generating a hot medium based on the heat of combustion of garbage at a waste disposal facility, the thermal energy of a gas or hot water at a relatively low temperature that has been just disposed of according to conventional technologies can be utilized effectively.

In the foregoing description of embodiments, a configuration in which the heat transfer medium is made to flow inside the container of a thermoelectric generator unit has been described as just an example. However, as long as the heat transfer medium can be brought into contact with the outer peripheral surface of a tubular thermoelectric generator, the container that houses the tubular thermoelectric generator may be omitted. For example, the flow rate of the hot water flowing through the internal flow path of a tubular thermoelectric generator may also be adjusted while sinking the tubular thermoelectric generator in a river. Alternatively, a tubular thermoelectric generator may be buried in snow and the snow in contact with the outer peripheral surface of the tubular thermoelectric generator may be used as the cold medium.

A method for generating electric power according to the present disclosure includes the steps of: making a first heat transfer medium flow through the flow path of the tubular thermoelectric generator of the thermoelectric generator system described above; bringing a second heat transfer medium at a different temperature from the first heat transfer medium into contact with the outer peripheral surface of the tubular thermoelectric generator; and getting either information about the operation condition of the thermoelectric generator system or a target power output level and controlling, by reference to either the information or the target power output level, the flow rate of at least one of the first heat transfer medium flowing through the flow path of the tubular thermoelectric generator and the second heat transfer medium that is in contact with the outer peripheral surface.

A thermoelectric generator system according to the present disclosure may be used as a power generator which utilizes the heat of hot water that has sprung from a hot spring or an exhaust gas exhausted from a car or a factory, for example.

While the present invention has been described with respect to exemplary embodiments thereof, it will be apparent to those skilled in the art that the disclosed invention may be modified in numerous ways and may assume many embodiments other than those specifically described above. Accordingly, it is intended by the appended claims to cover all modifications of the invention that fall within the true spirit and scope of the invention.

What is claimed is:

1. A thermoelectric generator system comprising a thermoelectric generator unit which performs thermoelectric generation using first and second heat transfer media at mutually different temperatures,
the thermoelectric generator unit including a tubular thermoelectric generator which has an outer peripheral surface and an inner peripheral surface and which generates electromotive force in an axial direction of the tubular thermoelectric generator based on a difference in temperature between the inner and outer peripheral surfaces,
the tubular thermoelectric generator including a stacked body in which a first layer made of a first material with a relatively low Seebeck coefficient and relatively high thermal conductivity and a second layer made of a second material with a relatively high Seebeck coefficient and relatively low thermal conductivity are stacked alternately one upon the other and of which the plane of stacking is inclined with respect to the axial direction on a cross section including the axis of the tubular thermoelectric generator,
the thermoelectric generator system further including a flow rate control system which controls the flow rate of at least one of the first heat transfer medium flowing through a flow path defined by the inner peripheral surface and the second heat transfer medium that is in contact with the outer peripheral surface by reference to either information about an operation condition of the thermoelectric generator system or a preset target power output level.

2. The thermoelectric generator system of claim 1, further comprising an input interface which gets the target power output level.

3. The thermoelectric generator system of claim 1, wherein the information about the operation condition of the thermoelectric generator system includes an electrical parameter indicating the power output level of the thermoelectric generator system.

4. The thermoelectric generator system of claim 3, wherein the flow rate control system sets the flow rate to be a value falling within a non-saturated region in which the power output level rises as the flow rate of at least one of the first and second heat transfer media increases, and
if the information indicates that the power output level has declined, the flow rate control system increases the flow rate of at least one of the first and second heat transfer media flowing through the thermoelectric generator unit.

5. The thermoelectric generator system of claim 1, wherein the information about the operation condition of the thermoelectric generator system includes the temperature of at least one of the first and second heat transfer media.

6. The thermoelectric generator system of claim 5, wherein the flow rate control system sets the flow rate to be a value falling within a non-saturated region in which the power output level rises as the flow rate of at least one of the first and second heat transfer media increases, and
if the information indicates that the difference in temperature between the first and second heat transfer media has narrowed, the flow rate control system increases the flow rate of at least one of the first and second heat transfer media.

7. The thermoelectric generator system of claim 1, wherein the thermoelectric generator system is connected to first and second supply sources of the first and second heat transfer media through first and second flow paths, respectively, and
at least one of a rate at which the first heat transfer medium is supplied from the first supply source and a rate at which the second heat transfer medium is supplied from the second supply source varies with time.

8. The thermoelectric generator system of claim 7, wherein the flow rate control system includes a first flow rate control section connected to the first flow path,
the first flow rate control section including:
a first storage container which stores the first heat transfer medium temporarily; and
a first regulator which regulates the flow rate of the first heat transfer medium that flows from inside of the first storage container into the thermoelectric generator unit so that the flow rate falls within a preset range.

9. The thermoelectric generator system of claim 8, wherein the first storage container is connected either in series to, or parallel with, the first flow path.

10. The thermoelectric generator system of claim 7, wherein the flow rate control system includes a second flow rate control section connected to the second flow path,
the second flow rate control section including:
a second storage container which stores the second heat transfer medium temporarily; and
a second regulator which regulates the flow rate of the second heat transfer medium that flows from inside of the second storage container into the thermoelectric generator unit so that the flow rate falls within a preset range.

11. The thermoelectric generator system of claim 10, wherein the second storage container is connected either in series to, or parallel with, the second flow path.

12. The thermoelectric generator system of claim 7, wherein the information about the operation condition of the thermoelectric generator system includes at least one of a rate at which the first heat transfer medium is supplied and a rate at which the second heat transfer medium is supplied.

13. The thermoelectric generator system of claim 7, wherein at least one of the first and second flow paths is a circuit which makes the heat transfer medium that has left the supply source go back to the same supply source again.

14. The thermoelectric generator system of claim 1, wherein the thermoelectric generator unit further includes a container to house the tubular thermoelectric generator inside, the container having a fluid inlet port and a fluid outlet port to make the second heat transfer medium flow inside the container and an opening into which the tubular thermoelectric generator is inserted.

15. A method for generating electric power by using the thermoelectric generator system of claim 1, the method comprising:
making a first heat transfer medium flow through the flow path of the tubular thermoelectric generator;
bringing a second heat transfer medium at a different temperature from the first heat transfer medium into contact with the outer peripheral surface of the tubular thermoelectric generator; and
getting either information about the operation condition of the thermoelectric generator system or a target power output level and controlling, by reference to either the information or the target power output level, the flow rate of at least one of the first heat transfer medium flowing through the flow path of the tubular thermoelectric generator and the second heat transfer medium that is in contact with the outer peripheral surface.
